(19) United States
(12) Patent Application Publication
(10) Pub. No.: US 2015/0325442 A1
(43) Pub. Date: Nov. 12, 2015

(54) Formulations of Solutions and Processes for Forming a Substrate Including a Dopant

(71) Applicant: Dynaloy, LLC, Kingsport, TN (US)

(72) Inventors: Monika Karin Wiedmann, Blountville, TN (US); Keith Allen Cox, Kingsport, TN (US); Leslie Shane Moody, Johnson City, TN (US); Junjia Liu, Kingsport, TN (US); Jessica Tanuwidjaja, Gray, TN (US); Kimberly Dona Pollard, Pendleton, IN (US); Kathryn Marie Kornau, Gray, TN (US); Spencer Erich Hochstetler, Kingsport, TN (US)

(73) Assignee: Dynaloy, LLC, Kingsport, TN (US)

(21) Appl. No.: 14/272,482

(22) Filed: May 7, 2014

(51) Int. Cl. H01L 21/225; H01L 21/22

(52) U.S. Cl. CPC H01L 21/225; H01L 21/2225

(57) ABSTRACT

Formulations of solutions and processes are described to form a substrate including a dopant. In particular implementations, the dopant can include arsenic (As) or phosphorus (P). In an embodiment, a dopant solution is provided that includes a solvent and a dopant-containing molecule. In a particular embodiment, the solvent of the dopant solution can have a flashpoint that is at least 55° C. In some cases, the dopant-containing molecule can have a molecular weight that is no greater than about 300 g/mol. In other instances, a ratio of a concentration of a dopant-containing molecule relative to a concentration of a contaminant is no greater than about 1×10¹⁰.

### BACKGROUND

Electronic devices typically include one or more components that are formed from semiconductor substrates. The semiconductor substrates include a number of transistors, sometimes on the order of thousands of transistors up to billions of transistors, to accomplish the functions of the electronic devices. Dopants can be added to semiconductor substrates to cause one or more regions of the semiconductor substrates to have particular electrical properties. For example, to produce regions of a semiconductor substrate having a concentration of electrons greater than a concentration of holes, phosphorous or arsenic can be added to the regions. These regions can be referred to as n-type regions. In another example, to produce regions of a semiconductor substrate having a concentration of holes greater than a concentration of electrons, boron can be added to the regions. These regions can be referred to as p-type regions.

In some cases, electronic device designers often attempt to improve the performance of electronic devices and/or increase the functionality of electronic devices while reducing cost, by adding more transistors per unit area to semiconductor substrates. Semiconductor device manufacturers have responded by continuing to decrease the size of the transistors formed on the semiconductor substrates. However, the extent of the decrease in size of the transistors may be limited due to limitations of processes used to form certain components of the transistor. For example, the decrease in size of the p-type or n-type regions that define, in part the junctions of a transistor, may be limited due to the ability of semiconductor manufacturers to effectively dope semiconductor substrates such that the concentration of the dopant in the semiconductor substrates is uniform and at a shallow enough depth to support a smaller transistor size.

As the size of transistor features decrease and the 14 nm is realized in high volume production and as transistors are being formed with three-dimensional shapes (e.g. finFETs), semiconductor manufacturers have encountered problems forming properly doped junctions and source/drain extensions, when using traditional doping methods, such as ion implantation. In some cases, semiconductor manufacturers have had problems disposing dopant atoms in a substantially uniform manner as a layer within a few nanometers of a surface of the semiconductor substrate. For example, ion implantation has been used to add dopants to a semiconductor substrate. However, ion implantation is a line of sight doping technique, and as the features of three-dimensional transistors decreases, the ion implantation devices are unable to access the entire surface of the substrate, which leads to a non-uniform doping of the substrate surface. Ion implantation may also suffer from limited lateral diffusion control, resulting in greater short channel effects, which decrease transistor performance. When the junctions of transistors included in electronic devices are not uniformly doped, the performance of electronic devices including these transistors can decrease due to the inability of the transistors to signal discrete on and off states. Furthermore, ion implantation of dopants can damage the surface of the substrates, which affects the performance of the junction.

### SUMMARY

This summary is provided to introduce concepts of formulations of solutions and processes to form a substrate including a dopant. Additional details of example formulations of solutions and example processes are further described below in the Detailed Description. This summary is not intended to identify essential features of the claimed subject matter, nor is it intended for use in determining the scope of the claimed subject matter.

In one embodiment, the disclosure is directed to a solution including a solvent having a flashpoint of at least about 55° C. and a dopant-containing molecule. The dopant-containing molecule can include a Group 15 element and the dopant-containing molecule can have a molecular weight no greater than 300 g/mol. In some cases, the dopant-containing molecule can include arsenic. In other cases, the dopant-containing molecule can include phosphorous.

In another embodiment, a solution can include a solvent and have a ratio of a concentration of a dopant-containing molecule, measured in parts per billion (ppb), relative to a concentration of a contaminant, measured in ppb, that is no greater than about 1×10¹⁰. The dopant-containing molecule can include a Group 15 element. In various embodiments, the concentration of the dopant-containing molecule can be included in a range of about 0.01% by weight for a total weight of the solution to about 10% by weight for a total weight of the solution. Additionally, the solution can have a total contaminant concentration of no greater than 20 parts per billion (ppb). Further, the solution can have a concentration of a single contaminant that is no greater than about 3 ppb. In some cases, the contaminant can include a metal, such as copper.

In an additional embodiment, a process can include preparing a solution including a solvent having a flashpoint of at least about 55° C. and a dopant-containing molecule. The dopant-containing molecule can include a Group 15 element and the dopant-containing molecule can have a molecular weight no greater than about 300 g/mol. The process can also include contacting a substrate with a solution. For example, the process can include contacting the substrate with the solution for a duration included in a range of about 1 minute to about 150 minutes and at a temperature included in a range of about 50° C. to about 150° C.

### BRIEF DESCRIPTION OF THE DRAWINGS

The detailed description is set forth with reference to the accompanying figures. In the figures, the left-most digit(s) of a reference number identifies the figure in which the reference number first appears. The use of the same reference numbers in different figures indicates similar or identical items or features.

FIG. 1 is a flow diagram of an embodiment of process to form a substrate including a dopant using a dopant solution.

FIG. 2 illustrates a cross-sectional view of a portion of a substrate having semiconductor material atoms and dopant atoms disposed in a region of the substrate.

FIG. 3 illustrates a cross-sectional view of a portion of a substrate including topographic features and having semiconductor material atoms and dopant atoms disposed in a region of the substrate.

FIG. 4 includes a first graph showing changes in concentration of arsenic atoms attached to atoms at a surface of a substrate that include a semiconductor material as a function of time according to different temperatures and different concentrations of arsenic-containing molecules in a dopant solution.

FIG. 5 includes a second graph showing changes in concentration of arsenic atoms attached to atoms of a surface of a substrate that includes a semiconductor material as a function of time according to different temperatures and different concentrations of arsenic-containing molecules in a dopant solution.

FIG. 6 includes a third graph showing changes in concentration of arsenicatoms attached to atoms of a surface of a substrate that includes a semiconductor material as a function of temperature according to different times of contact between the substrate and a dopant solution and different concentrations of arsenic-containing molecules in the dopant solution.

FIG. 7 includes a fourth graph showing changes in concentration of arsenic atoms attached to atoms of a surface of a substrate that includes a semiconductor material as a function of concentration according to different times of contact between the substrate and a dopant solution at different temperatures.

FIG. 8 includes a fifth graph showing changes in concentration of arsenic atoms attached to atoms of a surface of a substrate that includes a semiconductor material as a function of temperature according to different times of contact between the substrate and a dopant solution and the dopant solution having the same concentration of arsenic-containing molecules for each of the times of contact.

FIG. 9 includes a graph showing changes in concentration of phosphorus atoms attached bonded to atoms of a surface of a substrate that includes a semiconductor material as a function of time according to different temperatures and for dopant solutions including different phosphorous-containing molecules.

FIG. 10 includes a first graph showing the degradation of an amount of a first dopant in a tetraglyme solution over time, a second graph showing the degradation of an amount of a second dopant in a tetraglyme solution over time, and a third graph showing the degradation of an amount of a third dopant in a tetraglyme solution over time.

FIG. 11 includes a graph showing the degradation of an amount of a fourth dopant in a tetraglyme solution over time.

FIG. 12 includes a first table, a second table, and a third table showing amounts of trace elements in a dopant solution including triethylarsenate and DB acetate.

FIG. 13 includes a table showing amounts of trace elements on the surface silicon wafers under different processing conditions.

### DETAILED DESCRIPTION

This disclosure describes formulations of solutions and processes to form a substrate including a dopant. Some embodiments of formulations and processes described herein can be used in relation to monolayer doping techniques for adding dopants to substrates. The substrate can include a semiconductor material. For example, the substrate can include silicon (Si). In another example, the substrate can include germanium (Ge). In some cases, the substrate can include a combination of silicon and germanium (SiGe). The dopant can include a group 15 element. In one example, the dopant can include arsenic (As). In another example, the dopant can include phosphorous (P). As used herein, the term “group 15 element” refers to the elements included in group 15 of the new International Union of Pure and Applied Chemistry (IUPAC) numbering of the periodic table of the chemical elements. In particular, the group 15 elements as used herein include nitrogen (N), phosphorous (P), arsenic (As), antimony (Sb), and bismuth (Bi).

A dopant can be disposed within the substrate by contacting the substrate with a solution that includes a dopant-containing molecule. In some scenarios, the substrate can be immersed in the solution. In other cases, one or more surfaces of the substrate can be coated with the solution. As the substrate is contacted with the solution, dopant-containing molecules in the solution can attach to atoms on a surface of the substrate through bonding, physisorption, H-bonding, combinations thereof, and the like. As used herein, the term “attach” can refer to a direct bond between atoms or an indirect attachment, such as through one or more intermediate atoms or moieties. At least a portion of the dopant-containing molecules bonded to atoms on the surface of the substrate can then be induced to penetrate the surface of the substrate and be disposed within a body of the substrate.

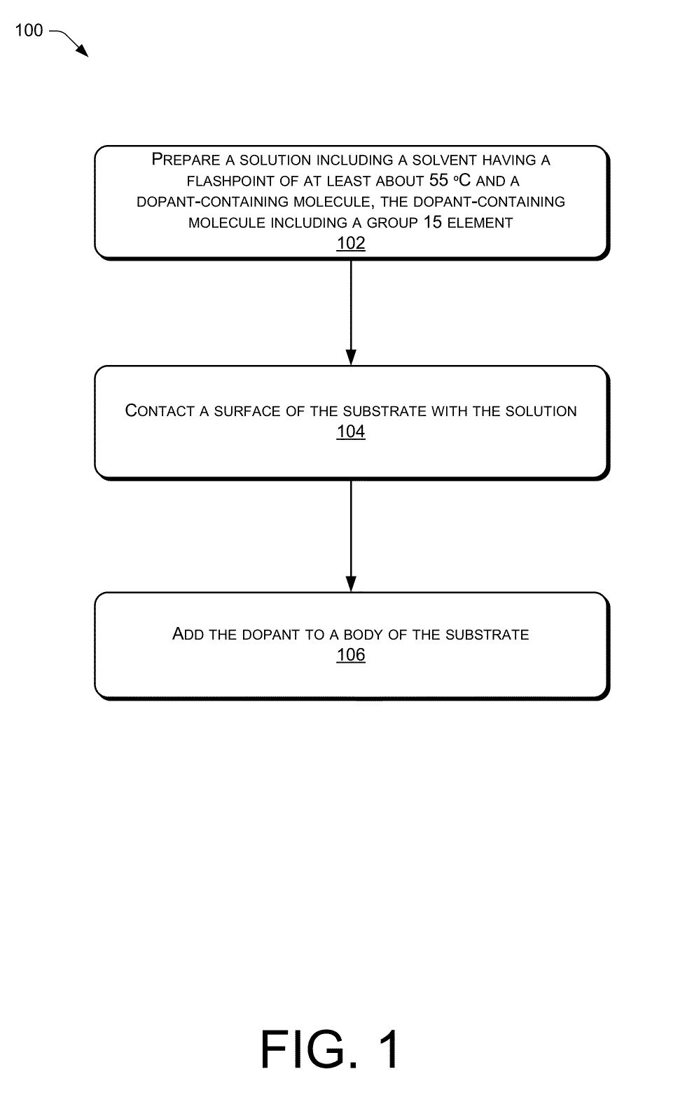

FIG. 1 is a flow diagram of a process 100 to form a substrate including a dopant. The substrate can be rigid, in some cases, and flexible in other cases. The substrate can include a semiconducting material. For example, the substrate can be a silicon-containing substrate. In some cases, the substrate can include at least about 40% by weight silicon, at least about 55% by weight silicon, or at least about 70% by weight silicon. In other cases, substantially all of the substrate can include silicon, no greater than about 95% by weight of the substrate can include silicon, or no greater than about 80% by weight of the substrate can include silicon. In one non-limiting illustrative example, Si atoms at a surface of the substrate can have a 100 orientation. In another non-limiting illustrative example, Si atoms at a surface of the substrate can have a 111 orientation. In yet another non-limiting illustrative example, Si atoms at a surface of the substrate can have a 110 orientation. In another non-limiting illustrative embodiment, the silicon substrate can have a layer of Ge deposited on the surface.

Additionally, the substrate can be a germanium-containing substrate. The substrate can include at least about 40% by weight germanium, at least about 55% by weight germanium, or at least about 70% by weight germanium. In other cases, substantially all of the substrate can include germanium, no greater than about 95% by weight of the substrate can include germanium, or no greater than about 80% by weight of the substrate can include germanium. In still other embodiments, the substrate can include a combination of silicon and germanium. In one non-limiting illustrative example, Ge atoms at a surface of the substrate can have a 100 orientation. In another non-limiting illustrative example, Ge atoms at a surface of the substrate can have a 111 orientation. In yet another non-limiting illustrative example, Ge atoms at a surface of the substrate can have a 110 orientation. In another non-limiting illustrative embodiment, the germanium substrate can have a layer of silicon or silicon oxide deposited on the surface.

In some cases, the substrate can include an oxide layer, such as a silicon oxide layer or a germanium oxide layer formed on one or more surfaces of the substrate. In an embodiment, the oxide layer can be a native oxide layer formed by the one or more surfaces of the substrate being exposed to oxygen. In another scenario, the oxide layer can be formed on the one or more surfaces of the substrate according to one or more processes that expose the substrate to oxygen or an oxygen-containing compound. In a particular case, the oxide layer can be formed by an entity using the substrate in a manufacturing process. The oxide layer can be formed with hydrogen-terminated atoms of the substrate.

At 102, the process 100 includes preparing a solution that includes a solvent and a dopant-containing molecule. The solution including the solvent and the dopant-containing molecule may sometimes be referred to herein as the “dopant solution.” In some cases, the dopant solution can include one or more solvents, such as a mixture of solvents. The dopant solution can also include one or more dopant-containing molecules. Additionally, the dopant-containing molecule can include a Group 15 element. In an embodiment, the dopant-containing molecule can include arsenic. For example, the dopant-containing molecule can include an organic arsenic molecule, an organoarsenic molecule, or an inorganic arsenic molecule. In an illustrative example, the dopant-containing molecule can include or be derived from tris(dimethylamino)arsine (TDMA). In another illustrative example, the dopant-containing molecule can include or be derived from an arsonic acid. In a particular illustrative example, the dopant-containing molecule can include an ester of an arsonic acid. In an additional illustrative example, the dopant-containing molecule can include an arsenate ester. In an additional particular illustrative example, the dopant-containing molecule can include triethylarsenate. In a further illustrative example, the dopant-containing molecule can include arsenic acid.

In other instances, the dopant-containing molecule can include phosphorus. For example, the dopant-containing molecule can include an organic phosphorus molecule, an organophosphorus molecule, or an inorganic phosphorus molecule. In an illustrative example, the dopant-containing molecule can include a phosphorus-containing acid. To illustrate, the dopant-containing molecule can include phosphorous acid. In another illustrative example, the dopant-containing molecule can include phosphoric acid. In an additional illustrative example, the dopant-containing molecule can include a phosphate ester. In a particular illustrative example, the dopant-containing molecule can include triethylphosphate. In a further illustrative example, the dopant-containing molecule can include a phosphonic acid. In still another illustrative example, the dopant-containing molecule can include a phosphonate ester. In an additional particular illustrative example, the dopant-containing molecule can include diethyl propylphosphonate. The dopant-containing molecule, in some instances, can also include tris(dimethylamino)phosphine or hexamethylphosphoramide.

Additionally, the dopant-containing molecule can include at least one functional group that is capable of reacting or interacting with atoms at the surface of a substrate. The reactive functional group or groups can include an alkenyl group or an alkynyl group. The reactive functional group or groups can also include a hydroxyl group. In one example, a reactive functional group of the dopant-containing molecule can include an acid functional group. Additionally, in various embodiments, the reactive functional group can include an aryl group, an amine group, an amide group, a nitro group, a carbonyl group, a thiol group, a dienophile, or a combination thereof. In some scenarios, the reactive functional group can include a dimethylamino group or a diakylamino group. In still other scenarios, the reactive functional group can include an acid group, including but not limited to a carboxylic acid group, a phosphonic acid group, a phosphoric acid group, a phosphorous acid group, an arsonic acid group, or an arsenic acid group.

Table 1 includes illustrative examples of dopant-containing molecules including arsenic that can be utilized in embodiments described herein. In addition, the dopant-containing molecules that may be utilized in embodiments herein can include ions of the compounds listed in Table 1, salts of the compounds listed in Table 1, oligomers of the compounds listed in Table 1, or a combination thereof

TABLE 1

| | Molecular | |
|---|---|---|
| Compound Number | Weight | Structure |
| 1 | 207.15 | 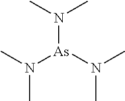 |
| 2 | 138 | 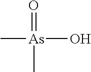 |
| 3 | 202.04 | 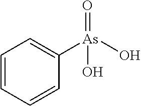 |
| 4 | 166.01 | 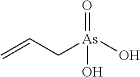 |
| 5 | 384.34 | 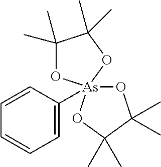 |
| 6 | 326.27 | 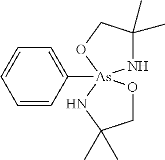 |
| 7 | 290.23 | 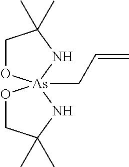 |
| 8 | 348.31 | 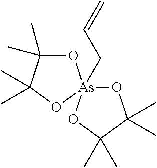 |
| 9 | 235.07 | 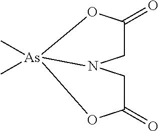 |
| 10 | 473.31 | 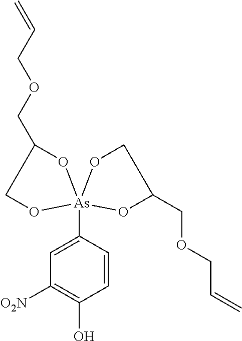 |
| 11 | 400.34 | 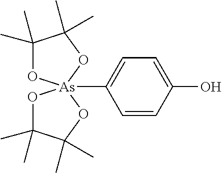 |
| 12 | 320.17 | 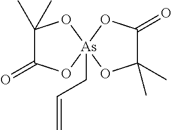 |
| 13 | 472.4 | 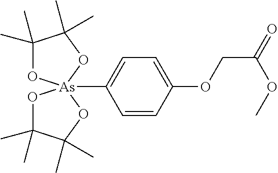 |
| 14 | 379.2 | 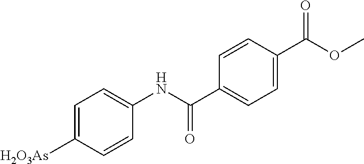 |
| 15 | 440.41 | 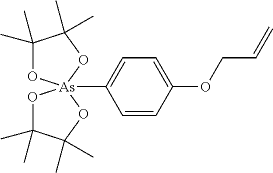 |
| 16 | | 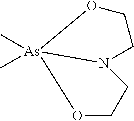 |
| 17 | | 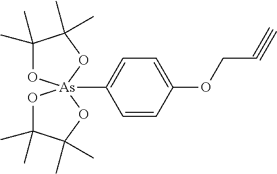 |
| 18 | | 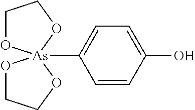 |
| 19 | | 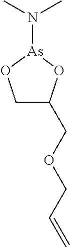 |
| 20 | | 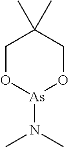 |
| 21 | | 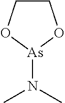 |
| 22 | | 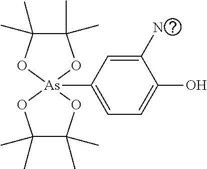 |
| 23 | | 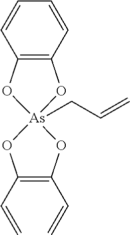 |
| 24 | | 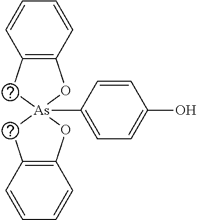 |
| 25 | | 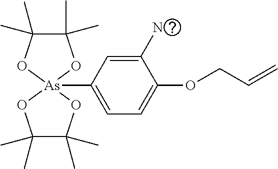 |
| 26 | | 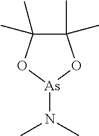 |
| 27 | | 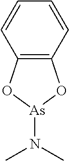 |
| 28 | | 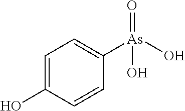 |
| 29 | | As₂O₃ |
| 30 | | 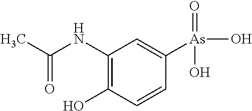 |
| 31 | | 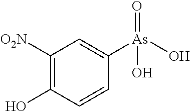 |
| 32 | | 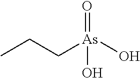 |
| 33 | | 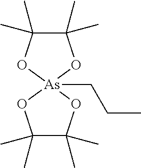 |
| 34 | | 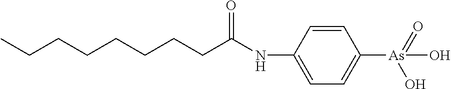 |
| 35 | | 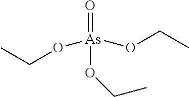 |
| 36 (arsenic acid, formed in situ by reaction of triethylarsenate with 3 equivalents of H₂O) | | 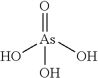 |
| 37 | | As₂O₅.nH2O |
| 38 (arsenic acid, formed in situ by reaction of arsenic (V) oxide hydrate with H₂O) | | 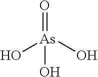 |
| 39 | | 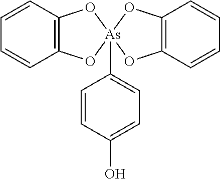 |
| 40 | | 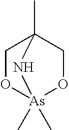 |
| 41 | | 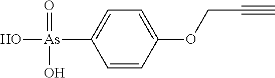 |
| 42 | | 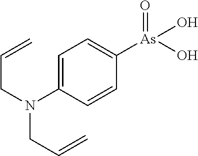 |
| 43 | | 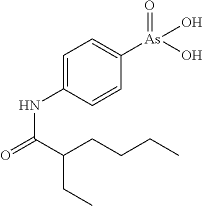 |
| 44 | | 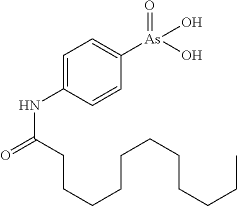 |
| 45 | | 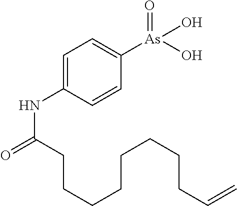 |

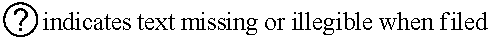

In addition, Table 2 includes illustrative examples of dopant-containing molecules including phosphorus that can be utilized in embodiments described herein. In addition, the dopant-containing molecules that may be utilized in embodiments herein can include ions of the compounds listed in Table 2, salts of the compounds listed in Table 2, oligomers of the compounds listed in Table 2, or a combination thereof.

TABLE 2

| | Molecular | |
|---|---|---|
| Compound Number | Weight | Structure |
| 1 | 180.18 | 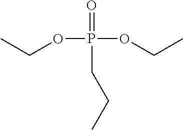 |
| 2 | 96.02 | 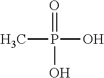 |
| 3 | 334.47 | 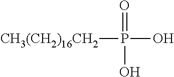 |
| 4 | 164.14 | 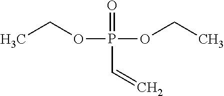 |
| 5 | 108.03 | 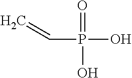 |
| 6 | 179.2 | 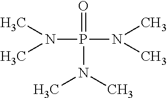 |
| 7 | 178.17 | 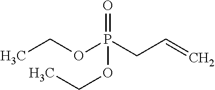 |
| 8 | 163.2 | 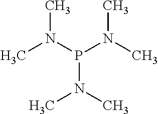 |
| 9 | 82 | 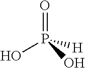 |
| 10 | 98 | 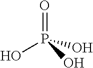 |
| 11 | 182.15 | 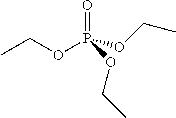 |

The dopant-containing molecule can also include a compound selected from a group consisting of:

(a)

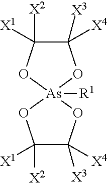

where R¹ is

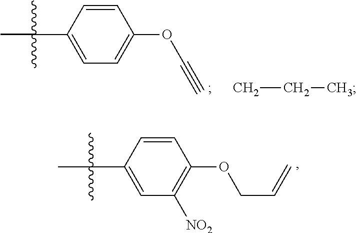

and x₁-x₄ are CH₃;
where R¹ is

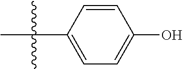 [SMILES: *c1ccc(O)cc1]

and x₁-x₄ are H;
where R¹ is CH₂—CH═CH₂ or

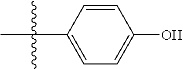 [SMILES: *c1ccc(O)cc1]

and when x₁ and x₃ are replaced by a double bond, x₂, x₄, and

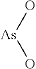

can form a ring structure of

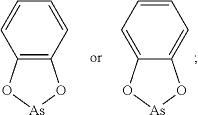

(b)

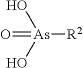

where R² is selected from the following:

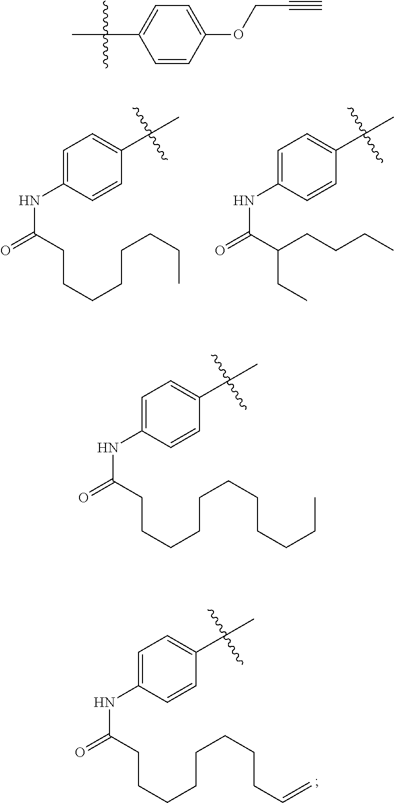

and

(c)

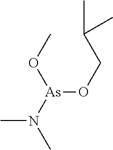

and

(d)

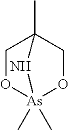

and

(e)

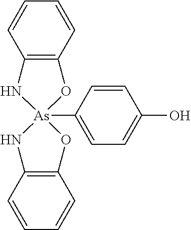

In some instances, the dopant-containing molecule can have a molecular weight that is no greater than about 400 g/mol, no greater than about 350 g/mol, no greater than about 300 g/mol, no greater than about 250 g/mol, or no greater than about 200 g/mol. The dopant-containing molecule can also have a molecular weight of at least about 75 g/mol, at least about 100 g/mol, at least about 150 g/mol, or at least about 175 g/mol. In an illustrative example, the dopant-containing molecule can have a molecular weight included in a range of about 60 g/mol to about 500 g/mol. In another illustrative example, the dopant-containing molecule can have a molecular weight included in a range of about 150 g/mol to about 300 g/mol. In a particular illustrative embodiment where the dopant-containing molecule includes phosphorous, the molecular weight of the dopant-containing molecule can be no greater than about 175 g/mol. In another particular illustrative embodiment where the dopant-containing molecule includes arsenic, the molecular weight of the dopant-containing molecule can be no greater than about 300 g/mol.

Furthermore, the solution can include at least about 0.005% by weight of the dopant-containing molecule for a total weight of the solution, at least about 0.05% by weight of the dopant-containing molecule for a total weight of the solution, at least about 0.5% by weight of the dopant-containing molecule for a total weight of the solution, or at least about 0.9% by weight of the dopant-containing molecule for a total weight of the solution. The solution can also include no greater than about 10% by weight of the dopant-containing molecule for a total weight of the solution, no greater than about 7% by weight of the dopant-containing molecule for a total weight of the solution, no greater than about 5% by weight of the dopant-containing molecule for a total weight of the solution, no greater than about 3% by weight of the dopant-containing molecule for a total weight of the solution, or no greater than about 1% by weight of the dopant-containing molecule for a total weight of the solution. In an illustrative example, the solution can include an amount of the dopant-containing molecule included in a range of about 0.001% by weight for a total weight of the solution to about 12% by weight for a total weight of the solution. In another illustrative example, the solution can include an amount of the dopant-containing molecule included in a range of about 0.005% by weight for a total weight of the solution to about 5% by weight for a total weight of the solution. In a further illustrative example, the solution can include an amount of the dopant-containing molecule included in a range of about 0.1% by weight for a total weight of the solution to about 1% by weight for a total weight of the solution.

The solvent of the dopant solution can include a glycol, a glycol ether, a glycol diether, or a carboxylate of a glycol ether. In an illustrative example, the solvent can include diethylene glycol monobutyl ether (DB) acetate. In another illustrative example, the solvent can include tetraethylene glycol dimethyl ether (tetraglyme). In another illustrative example, the solvent can include diethylene glycol monobutylether, (DB). In another illustrative example, the solvent can include tetraethyleneglycol. Additionally, the solvent can include water. Further, the solvent can include mesitylene. In some cases, the solvent can also include dimethyl sulfoxide (DMSO). In other instances, the solvent can include N-methylpyrrolidone (NMP) or 1-formylpiperdine.

In an embodiment, the solvent can have a flashpoint of at least about 45° C., at least about 50° C., at least about 55° C., or at least about 60° C. The solvent can also have a flashpoint no greater than about 200° C., or no greater than about 150° C. In an illustrative example, the solvent can have a flashpoint included in a range of about 40° C. to about 250° C. In another illustrative example, the solvent can have a flashpoint included in a range of about 55° C. to about 175° C. In a further illustrative example, the solvent can have a flashpoint included in a range of about 80° C. to about 150° C. In some cases, the dopant solution may have a flashpoint that is at least approximately equal to or greater than a minimum temperature capable of causing attachment between at least a portion of the atoms at a surface of a substrate and a dopant-containing compound in the dopant solution. In an illustrative embodiment, the flashpoint of the dopant solution may be within a range of about 25° C. to about 150° C. or within a range of about 40° C. to about 80° C. greater than the minimum temperature capable of causing attachment between atoms at a surface of the substrate and the dopant-containing compound of the dopant solution.

The dopant solution can also include a contaminant. In some cases, the dopant solution can include a plurality of contaminants. For example, the contaminant can include copper. In another example, the contaminant can include iron. In an additional example, the contaminant can include aluminum. In a further example, the contaminant can include gold, silver, boron, beryllium, bismuth, calcium, cadmium, chromium, gallium, germanium, potassium, lithium, magnesium, manganese, molybdenum, potassium, nickel, lead, niobium, antimony, tin, strontium, tantalum, thallium, titanium, thorium, uranium, vanadium, tungsten, zinc, zirconium, or a combination thereof. In some cases, when the dopant-containing molecule includes arsenic, phosphorous can be a contaminant. In other situations, when the dopant-containing molecule includes phosphorous, arsenic can be a contaminant.

In some cases, the contaminant can have a concentration of no greater than about 20 parts per billion (ppb), no greater than about 10 ppb, no greater than about 5 ppb, no greater than about 1 ppb, no greater than about 0.5 ppb, or no greater than about 0.1 ppb. In an illustrative example, the contaminant can have a concentration included in a range of about 0.01 ppb to about 25 ppb. In another illustrative example, the contaminant can have a concentration included in a range of about 0.1 ppb to about 1 ppb. In a further illustrative example, the contaminant can have a concentration included in a range of about 0.5 ppb to about 2 ppb. In embodiments where the dopant solution includes a plurality of contaminants, the solution can have a total contaminant concentration of no greater than about 30 ppb, no greater than about 25 ppb, no greater than about 20 ppb, no greater than about 15 ppb, no greater than about 10 ppb, or no greater than about 5 ppb. In an illustrative embodiment, the dopant solution can have a total contaminant concentration included in a range of about 1 ppb to about 40 ppb. In another illustrative embodiment, the solvent can have a total contaminant concentration included in a range of about 5 ppb to about 20 ppb.

The dopant solution can also have a ratio of a concentration of a dopant-containing molecule, measuring in ppb, relative to a contaminant concentration, measured in ppb, that is no greater than about 1×10¹⁰, no greater than about 5×10¹⁰, no greater than about 2×10⁹, no greater than about 1×10⁹, no greater than about 5×10⁸, no greater than about 1×10⁸, or no greater than about 5×10⁷. In an illustrative example, the solution can have a ratio of a concentration of a dopant-containing molecule relative to a contaminant concentration included in a range of about 1×10⁷ to about 4×10⁹. In another illustrative example, the solution can have a ratio of a concentration of a dopant-containing molecule relative to a contaminant concentration included in a range of about 2×10⁸ to about 1×10⁹. In an additional illustrative example, the solution can have a ratio of a concentration of a dopant-containing molecule relative to a contaminant concentration included in a range of about 4×10⁸ to about 8×10⁸. In some instances, the contaminant concentration can include a total contaminant concentration. In other instances, the contaminant concentration can include a concentration of one or more contaminants.

In various embodiments, the solution can include an additive. In some cases, the solution can include one or more additives. The solution can include at least about 0.0001% by weight additive for a total weight of the solution, at least about 0.001% by weight additive for a total weight of the solution, or at least about 0.01% by weight additive for a total weight of the solution. The solution can also include no greater than about 20% by weight additive for a total weight of the solution, no greater than about 10% by weight additive for a total weight of the solution, or no greater than about 1% by weight additive for a total weight of the solution. In an illustrative example, the solution can include an amount of an additive that is included in a range of about 0.0005% by weight for a total weight of the solution to about 10% by weight for a total weight of the solution. In another illustrative example, the solution can include an amount of additive that is included in a range of about 0.001% by weight for a total weight of the solution to about 5% by weight for a total weight of the solution. In an additional illustrative example, the solution can include an amount of an additive that is included in a range of about 0.01% by weight for a total weight of the solution to about 1% by weight for a total weight of the solution. In some cases the amount of additive included in the solution can include an amount of a single additive. In other cases, the amount of additive included in the solution can include an respective amount of each of a plurality of additives.

In an example, the additive can include water. In another example, the additive can include hydrochloric acid. In an additional example, the additive can include hydroquinone. In a further example, the additive can include nitric acid. In a still further example, the additive can include oxalic acid. In other examples, the additive can include benzoquinone. Additionally, the additive can include sulfuric acid. Furthermore, the additive can include azobisisobutyronitrile. The additive can also include a corrosion inhibitor. To illustrate, the additive can include an antioxidant to minimize oxidation of the solution, to minimize oxidation of a surface of a substrate, or both. In other cases, an additive can oxidize the surface of the substrate. The additive can also act as a catalyst for a reaction causing the dopant-containing molecule to attach to atoms on a surface of a substrate. In some situations, the additive can include a surface modifier to modify a surface of the substrate either before or after the dopant-containing molecule attaches to atoms on the surface of the substrate. In still other instances, the additive can include a trace metal chelator to bind trace metal contaminants included in the solution. In still other instances, the additive can include a molecule that reacts with the surface of the substrate and limits the number of instances of the dopant-containing molecule that can attach to the surface of the substrate.

The solution can be prepared by combining the solvent and the dopant-containing molecule, such as via mixing, at a suitable temperature and for a sufficient duration for the dopant-containing molecule to dissolve in the solvent or for the dopant-containing molecule to be miscible in the solvent. In some cases, the solution can be prepared by mixing two or more substances. Additionally, the dopant can be generated by mixing two materials into the solvent to form the in situ dopant-containing molecule. In an illustrative example, arsenic acid can be produced by mixing triethylarsenate and water in the solvent.

In an embodiment, a solvent included in the solution can be capable of dissolving the dopant-containing molecule or the dopant-containing molecule can be miscible in the solvent at a temperature of no greater than about 80° C., no greater than about 65° C., no greater than about 50° C., no greater than about 35° C., or no greater than about 25° C. In another embodiment, the solvent can be capable of dissolving the dopant-containing molecule or the dopant-containing molecule can be miscible in the solvent at a temperature of at least 2° C., at least 8° C., at least 15° C., or at least about 20° C. In an illustrative embodiment, the solvent can be capable of dissolving the dopant-containing molecule or the dopant-containing molecule can be miscible in the solvent at a temperature within a range of about 20° C. to about 35° C. Additionally, the dopant-containing molecule and the solvent can be mixed at a pressure within a range of about 10 pounds/in.² (psi) to about 25 psi. Furthermore, in some situations, the solvent can be subjected to a drying operation before being combined with the dopant-containing molecule. For example, the solvent can be dried by adding a drying agent, by washing the solvent with a drying solution, by distilling the solvent in the presence of a drying agent in an ambient environment or while pulling a vacuum, by distilling water from the solvent in an ambient environment or while pulling a vacuum, through the use rotary evaporation techniques, through the use of thin-film evaporation techniques, through the use of azeotropic distillation techniques, or a combination thereof.

In an illustrative embodiment, the solvent can be dried in a rotary evaporator. In some examples, the solvent can be dried in the rotary evaporator at a temperature included in a range of about 50° C. to about 150° C. In other examples, the solvent can be dried in the rotary evaporator at a temperature included in a range of about 65° C. to about 85° C. Additionally, the solvent can be dried by rotating the rotary evaporator at a speed included in a range of about 50 rotations per minute (rpm) to about 200 rpm. In other cases, the solvent can be dried by rotating the rotary evaporator at a speed included in a range of about 100 rpm to about 150 rpm. Further, the solvent can be dried in the rotary evaporator under a vacuum. To illustrate, the solvent can be dried in the rotary evaporator at a pressure included in a range of about 2 Torr to about 100 Torr. In additional situations, the solvent can be dried in the rotary evaporator at a pressure included in a range of about 4 Torr to about 20 Torr. The solvent can also be dried for a duration included in a range of about 30 minutes to about 10 hours. In some embodiments, the solvent can be dried for a duration included in a range of about 4 hours to about 8 hours. In various embodiments, the conditions for drying the solvent can depend on an amount of solvent being dried. After drying the solvent, an amount of water included in the solvent can be no greater than about 0.25% by weight, no greater than about 800 ppm, no greater than about 500 ppm, or no greater than about 200 ppm.

At 104, the process 100 includes contacting a surface of a substrate with the solution. “Contacting” as used herein may refer to one or more processes for bringing the surface of the substrate into physical contact with a material, such as immersion, spin coating, spraying, vapor exposure, and the like. The substrate can be contacted with the solution, in some cases, in an inert environment, such as a nitrogen environment or an argon environment.

In some cases, the surface of the substrate can be pre-treated before contacting the surface of the substrate with the solution. For example, an oxide layer can be removed from the surface of the substrate. In addition, pretreatment of the surface of the substrate can result in atoms at the surface of the substrate being hydrogen terminated. In other cases, the surface of the solution can be contacted with the solution without any pretreatment of the substrate.

In an illustrative example, the surface of the substrate can be pretreated by contacting the surface of the substrate with an acid. To illustrate, the surface of the substrate can be contacted with a substrate pretreatment solution including hydrofluoric acid. In an embodiment, the substrate pretreatment solution can include an amount of hydrofluoric acid included in a range of about 0.05% by weight for a total weight of the substrate pretreatment solution to about 0.5% by weight for a total weight of the substrate pretreatment solution. Additionally, the substrate pretreatment solution can include an amount of hydrofluoric acid included in a range of about 0.1% by weight for a total weight of the substrate pretreatment solution to about 0.3% by weight for a total weight of the substrate pretreatment solution. The substrate pretreatment solution can also have a ratio of water:concentrated hydrofluoric acid (e.g. about 49% hydrofluoric acid solution) included in a range of about 200:1 to about 1000:1. Further, the substrate can be contacted with the substrate pretreatment solution for a duration of no greater than about 10 minutes, a duration no greater than about 8 minutes, a duration no greater than about 5 minutes, a duration no greater than about 2 minutes, or a duration no greater than about 30 seconds. The substrate may be treated with the substrate pretreatment solution at a temperature within a range of about 10° C. to about 35° C. After contacting the surface of the substrate with the substrate pretreatment solution, the substrate can be washed using water, such as water having a resistivity included in a range of about 10 megohm (Me) to about 20 MΩ. The substrate can then be dried by applying a stream of gas to the substrate, such as an N₂ stream, a stream of air, or a stream of O₂.

The substrate can be contacted with the dopant solution at a temperature of at least about 10° C., at least about 25° C., at least about 40° C., or at least about 55° C. Additionally, the substrate can be contacted with the dopant solution at a temperature no greater than about 150° C., no greater than about 130° C., no greater than about 110° C., no greater than about 90° C., or no greater than about 70° C. In an illustrative example, the substrate can be contacted with the dopant solution at a temperature included in a range of about 10° C. to about 160° C. In another illustrative example, the substrate can be contacted with the dopant solution at a temperature included in a range of about 50° C. to about 130° C. In an additional illustrative example, the substrate can be contacted with the dopant solution at a temperature included in a range of about 60° C. to about 120° C. In some cases, the substrate can be contacted with the dopant solution at a temperature and for a duration capable of causing a reaction between the dopant-containing molecule and atoms at the surface of the substrate. In a particular embodiment, the substrate can be contacted with the dopant solution at a temperature less than a flashpoint of the solvent of the dopant solution.

Additionally, the substrate can be contacted with the dopant solution for a duration of at least about 1 minute, at least about 10 minutes, at least about 25 minutes, at least about 40 minutes, or at least about 60 minutes. The substrate can also be contacted with the dopant solution for a duration of no greater than about 150 minutes, no greater than about 130 minutes, no greater than about 110 minutes, no greater than about 90 minutes, or no greater than about 75 minutes. In an illustrative example, the substrate can be contacted with the dopant solution for a duration included in a range of about 0.5 minutes to about 180 minutes. In another illustrative example, the substrate can be contacted with the dopant solution for a duration included in a range of about 30 minutes to about 150 minutes. In an additional illustrative example, the substrate can be contacted with the dopant solution for a duration included in a range of about 60 minutes to about 120 minutes.

In some cases, the substrate can be contacted with the dopant solution at a temperature and for a duration capable of causing a reaction between the dopant-containing molecule and atoms at the surface of the substrate. Thus, as the substrate is contacted with the dopant solution, a reaction may occur between instances of the dopant-containing molecule and atoms at the surface of the substrate and at least a portion of the instances of the dopan atom can become associated with atoms at a surface of the substrate. For example, one or more functional groups of instances of the dopant-containing molecule can bond with one or more respective atoms at the surface of the substrate. To illustrate, alkene functional groups or alkyne functional groups of instances of a dopant-containing molecule can react with hydrogen-terminated silicon atoms at the surface of the substrate through hydrosilylation. Additionally, alcohol functional groups of instances of a dopant-containing molecule can react with hydrogen-terminated silicon atoms at the surface of the substrate through formation of a silicon-oxygen-carbon linkage and dihydrogen generation. Furthermore, dimethylamino or dialkylamino functional groups of instances of the dopant-containing material can react with atoms at the surface of the substrate. In other scenarios, the dopant-containing molecule can include arsonic acid functional groups (R—AsO₃H₂) that react with silicon atoms at the surface of the substrate.

When the dopant-containing molecules including arsenic react with atoms at the surface of the substrate, dopant atoms attached to the atoms of the substrate surface can include arsenic atoms that have different oxidation states. For example, at least a portion of the arsenic atoms can include arsenic (0). In another example, at least a portion of the arsenic atoms can include arsenic (III) and/or arsenic (V).

The concentration of dopant atoms associated with atoms at the surface of the substrate can include at least about 2×10¹³ dopant atoms/cm², at least about 6×10¹³ dopant atoms/cm², at least about 1×10¹⁴ dopant atoms/cm², or at least about 4×10¹³ dopant atoms/cm². Additionally, the concentration of dopant atoms associated with atoms at the surface of the substrate can be no greater than about 1×10¹⁵ dopant atoms/cm², no greater than about 8×10¹⁴ dopant atoms/cm², or no greater than about 5×10¹⁴ dopant atoms/cm². In an illustrative example, the concentration of dopant atoms associated with atoms at the surface of the substrate can be included in a range of about 8×10¹² dopant atoms/cm² to about 3×10¹⁵ dopant atoms/cm². In another illustrative example, the concentration of dopant atoms associated with atoms at the surface of the substrate can be included in a range of about 5×10¹³ dopant atoms/cm² to about 5×10¹⁴ dopant atoms/cm². In an additional illustrative example, the concentration of dopant atoms associated with atoms at the surface of the substrate can be included in a range of about 8×10¹³ dopant atoms/cm² to about 4×10¹⁴ dopant atoms/cm².

In some scenarios, the substrate can be rinsed after being contacted by the dopant solution. In one embodiment, the substrate can be rinsed with the solvent included in the dopant solution. In certain instances, the substrate can undergo a rinse using a low boiling point solvent. An example of a low boiling solvent can be isopropanol. In yet another illustrative example, the substrate can be rinsed with water. In certain cases, the substrate can also undergo one or more drying operations. In one case, the substrate can be dried after being contacted with the dopant solution. In another case, the substrate can be dried after being rinsed with the solvent of the dopant solution. In a further scenario, rinsing the substrate with the low-boiling point solvent can be part of a process to dry the substrate. In some cases, the substrate may not undergo rinsing after modifying the surface of the substrate and before contacting the substrate with a dopant solution.

In an embodiment, rinsing can include contacting the substrate with a heated solvent. In a particular embodiment, the temperature of the solvent can be room temperature, such as within a range of about 15° C. to about 25° C., up to a minimum temperature capable of initiating a reaction with the dopant solution. In some cases, the heated solvent can be applied to a substrate after contacting the surface of the substrate with a surface modification solution or after the substrate has been contacted with a dopant solution. In one embodiment, after contacting the substrate with the heated solvent, the substrate can be rinsed with either water or a low boiling organic solvent.

In a particular illustrative embodiment, the processes described with respect to operation 104 can be repeated. To illustrate, after the substrate is contacted with the dopant solution, the substrate can undergo an additional process to contact the substrate with the dopant solution. In some situations, the substrate can be rinsed each time the substrate is contacted with a dopant solution, while in other cases, the substrate may not be rinsed after at least one of the applications of the dopant solution to the substrate. In some instances, the duration and temperature of subsequent operations of contacting the substrate with the dopant solution can be similar to the duration and temperature of a previous operation of contacting the substrate and the dopant solution. In other instances, the duration and temperature of subsequent operations directed to contacting the substrate with the dopant solution can be different than the duration and temperature of a previous operation of contacting the substrate with the dopant solution. Accordingly, the use of more than one dopant solution for the corresponding dopant layers can be employed.

At 106, the process 100 includes adding the dopant to a body of the substrate. In some cases, the dopant can be added to the body of the substrate via diffusion. In particular instances, dopant atoms originating from instances of the dopant-containing molecules and attached to the surface of the substrate may diffuse from the surface of the substrate into the body of the substrate under suitable conditions.

In particular embodiments, during a thermal treatment, the dopant atoms may diffuse to a particular depth with respect to the surface of the substrate. In one example, the dopant atoms may diffuse into the body of the substrate such that the peak concentration of the dopant is achieved at a depth of no greater than about 20 nm from the surface of the substrate, no greater than about 10 nm from the surface of the substrate, no greater than about 7 nm from the surface of the substrate, or no greater than about 5 nm from the surface of the substrate. Additionally, the distribution of dopant in the substrate may be such that substantially no dopant in the silicon is present at a distance of 20 nm from a location of the peak dopant concentration in the substrate, at a distance of 15 nm from a location of a peak dopant concentration in the substrate, at a distance of 10 nm from a location of the peak dopant concentration in the substrate, or at a distance of 7 nm from the a location of the peak dopant concentration in the substrate. For example, substantially no dopant may be present at a distance of at least about 2 nm from a surface of the substrate, at least about 3 nm from a surface of the substrate, at least about 4 nm from a surface of the substrate, or at least about 5 nm from a surface of the substrate. In an illustrative embodiment, the dopant atoms can diffuse into the body of the substrate such that a location of the peak concentration of the dopant is achieved at a depth within a range of about 0.5 nm to about 9 nm. In another illustrative embodiment, the arsenic atoms can diffuse into the body of the substrate to a depth within a range of about 1 nm to about 5 nm.

In an embodiment, adding the dopant to the body of the substrate can include an anneal process. In some cases, the anneal process can be conducted in an inert gas environment, such as a nitrogen environment or an argon environment. In one embodiment, the anneal process can have a duration of at least 10 milliseconds, at least 0.5 seconds, at least 4 seconds, at least 20 seconds, at least 30 seconds, or at least 45 seconds. In another embodiment, the anneal process can have a duration of no greater than 135 seconds, no greater than 100 seconds, no greater than 75 seconds, or no greater than 50 seconds. In an illustrative embodiment, the anneal process can have a duration within a range of about 10 seconds to about 90 seconds, within a range of about 25 seconds to about 75 seconds, or within a range of about 30 seconds to about 60 seconds. In another illustrative embodiment, the anneal process can have a duration within a range of about 10 milliseconds to about 700 milliseconds.

In an additional embodiment, the anneal process can be conducted at a temperature of at least 600° C., at least 750° C., at least 900° C., or at least 1000° C. In a further embodiment, the anneal process can be conducted at a temperature of no greater than about 1200° C., no greater than about 1125° C., or no greater than about 1050° C. In an illustrative embodiment, the anneal process can be conducted at a temperature within a range of about 800° C. to about 1150° C. or within a range of about 900° C. to about 1050° C.

In some cases, prior to the annealing operation, a capping layer can be applied to the surface of the substrate. The capping layer can overlie the dopant-containing molecules associated with atoms at the surface of the substrate. In one embodiment, the capping layer can include SiO₂. In addition, the capping layer can include silicon nitride. Further, the camping layer can include silicon oxynitride. In another embodiment, the capping layer can include silicon oxide formed using a plasma enhanced tetraethyl-orthosilicate process. In another embodiment, the capping layer can include silicon oxide formed with a liquid spin-on dielectric material. In some cases, the capping layer can have a thickness of at least 10 nm, at least 25 nm, or at least 40 nm. In other situations, the capping layer can have a thickness no greater than about 300 nm, no greater than about 200 nm, or no greater than about 100 nm. In an illustrative embodiment, the capping layer can have a thickness within a range of about 15 nm to about 55 nm or within a range of about 25 nm to about 45 nm. In a particular embodiment, after annealing of the substrate, the capping layer can be removed. For example, the capping layer can be removed by contacting the capping layer with a solution of dilute hydrofluoric acid.

Although the process 100 includes operations described with respect to blocks 102-106, in some cases, the process 100 can include additional operations. To illustrate, once the dopant has been added to the substrate, one or more additional operations can be performed to form a semiconductor device that includes ultra-shallow junctions formed from the doped substrate. In another illustration, the substrate can be contacted with a material that blocks some silicon atoms at the surface of the substrate from forming a bond with the arsenic-containing compound. In a particular situation, the blocking compounds may include reactive moieties that are analogous to those found on the dopant-containing molecule, but the blocking compounds do not include a dopant atom or atoms themselves.

In some cases, the dopant atoms attached to atoms of the surface of the substrate can be removed from at least a portion of the surface of the substrate. For example, at least a portion of the surface of the substrate can be contacted with one or more solutions. The solutions used to remove the dopant atoms attached to the surface of the substrate can include a solution having hydrofluoric acid. In an illustrative example, the solution can include an amount of hydrofluoric acid included in a range of about 0.1% by weight for a total weight of the solution to about 1% by weight for a total weight of the solution. In some cases, the hydrofluoric acid solution can be applied to the surface of the substrate multiple times to remove the dopant atoms from the surface of the substrate. The hydrofluoric acid solution can be applied to the surface of the substrate for a period of time included in a range of about 30 seconds to about 10 minutes. In another illustrative example, the hydrofluoric acid solution can be applied to the surface of the substrate for a period of time included in a range of about 1 minute to about 5 minutes.

In some additional embodiments, a portion of the surface of the substrate can be contacted with a solution including nitric acid, phosphoric acid, or a combination thereof, in addition to or as an alternative to the application of the hydrofluoric acid solution to the surface of the substrate. An amount of nitric acid included in the nitric acid solution can be included in a range of about 0.2% by weight for a total weight of the solution to about 15% by weight for a total weight of the solution. The nitric acid solution can be applied to the substrate for a duration included in a range of about 5 minutes to about 40 minutes. Additionally, an amount of phosphoric acid included in the phosphoric acid solution can be included in a range of about 10% by weight for a total weight of the solution to about 35% by weight for a total weight of the solution. The phosphoric acid solution can be applied to the substrate for a duration included in a range of about 5 minutes to about 40 minutes.

In addition, a hydrogen peroxide solution can also be applied to the surface of the substrate to remove at least a portion of the dopant atoms from the surface of the substrate. In some instances, the solution can include an amount of hydrogen peroxide included in a range of about 1% by weight for a total weight of the solution to about 35% by weight for a total weight of the solution. The hydrogen peroxide solution can also be applied to the surface of the substrate more than once to remove dopant atoms from at least a portion of the surface of the substrate. The hydrogen peroxide solution can be applied to the surface of the substrate for a period of time included in a range of about 10 seconds to about 2 minutes. In another illustrative example, the hydrogen peroxide solution can be applied to the surface of the substrate for a period of time included in a range of about 15 seconds to about 1 minute.

In a particular embodiment, the substrate can be contacted with both a hydrofluoric acid solution and a hydrogen peroxide solution to remove at least a portion of the dopant atoms from the surface of the substrate. For example, at least a portion of the surface of the substrate can be contacted with a hydrofluoric acid solution, following by contacting the at least a portion of the surface of the substrate with a hydrogen peroxide solution, and then contacting the at least a portion of the surface of the substrate with the hydrofluoric acid solution. In some cases, the first application of the hydrofluoric acid solution to the at least a portion of the surface of the substrate can be performed after an initial application of the hydrogen peroxide solution to the at least a portion of the substrate.

Additionally, it should be noted that portions of the surfaces of the substrates described with respect to the process 100 may include exposed atoms of the substrate, such as exposed silicon atoms and/or exposed germanium atoms, while other portions of the surfaces of the substrate may be covered with particular materials, such as photoresist or hard masks.

Further, the order in which the operations of the process 100 are described is not intended to be construed as a limitation, and any number of the described operations can be combined in any order and/or in parallel to implement the process 100. In still further embodiments, although in some situations, the dopant solution may be described as including a solvent, in other cases, the dopant solution may not include a solvent.

Furthermore, this disclosure describes formulations and processes that may be used to form a uniformly doped substrate that may include three-dimensional transistor structures with junctions having depths less than 20 nm. In some cases, the substrates formed according to embodiments herein can include silicon-on-insulator (SOI) substrates, germanium-on-insulator substrates, conventional silicon substrates, silicon substrates that can present multiple crystal orientations (e.g., substrates having a shaped fin where the orientation of Si atoms may be a function of the position of the Si atoms on the three dimensional structure), conventional germanium substrates, or a combination thereof.

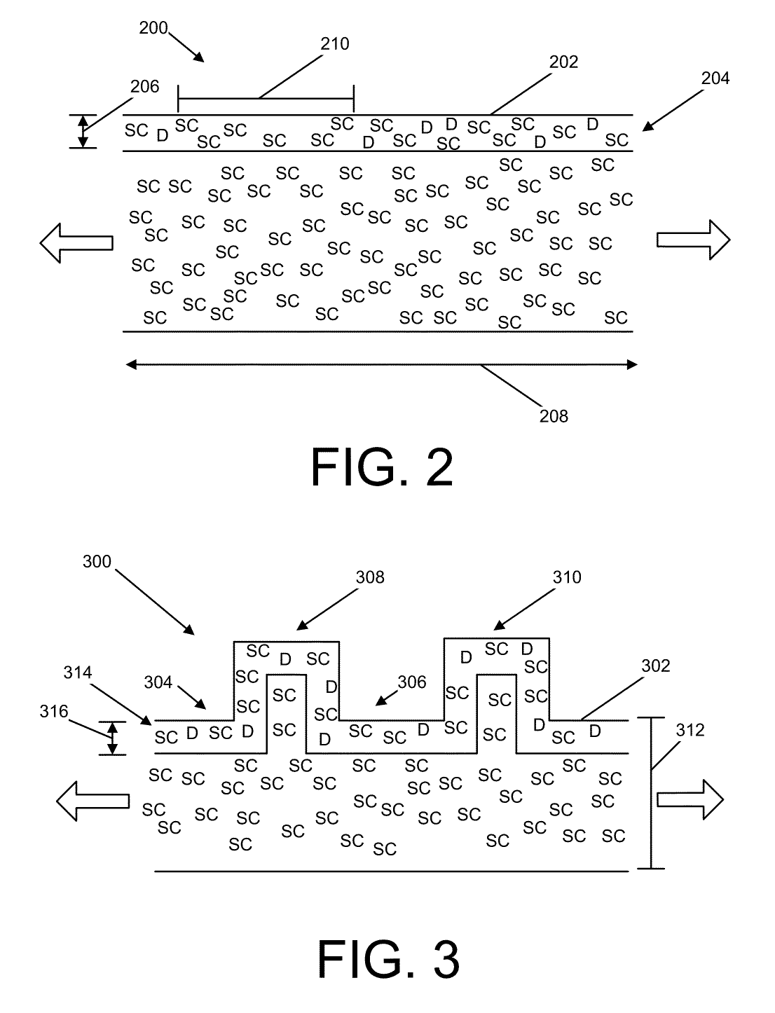

FIG. 2 illustrates a cross-sectional view of a portion of a substrate 200 having semiconductor material atoms labeled as “SC” and dopant atoms labeled as “D” disposed in a region of the substrate. The semiconductor material atoms can include silicon, germanium, or a combination thereof. Additionally, the dopant atoms can include a group 15 element. In some cases, the dopant atoms can include arsenic. In other situations, the dopant atoms can include phosphorus.

In a particular embodiment, the substrate 200 includes a surface 202. The surface 202 can be substantially planar. In the illustrative embodiment of FIG. 2, the substrate 200 includes a region 204 that includes dopant atoms and semiconductor material atoms. The region 204 can be substantially disposed along a contour of the surface 202 of the substrate 200, in some embodiments. The dopant atoms can be disposed in the region by one or more of the embodiments described with respect to the process 100 of FIG. 1. In an illustrative embodiment, the region 204 can have a depth 206. The depth 206 can be relative to the surface 202. The substrate 200 can also have a width 208.

In some cases, the depth 206 can be no greater than about 20 nm, no greater than about 16 nm, no greater than about 12 nm, no greater than about 8 nm, or no greater than about 4 nm. In an illustrative example, the depth 206 can be included in a range of about 0.3 nm to about 30 nm. In another illustrative example, the depth can be included in a range of about 2 nm to about 10 nm. In various instances, dopant atoms can be absent from portions outside of the region 204. In an embodiment, an amount of dopant atoms outside of the region 204 can be no greater than about 4% of the amount of dopant atoms in the region 204, no greater than about 2% of the amount of dopant atoms in the region 204, no greater than about 1% of the amount of dopant atoms in the region 204, no greater than about 0.5% of the amount of dopant atoms in the region 204, or no greater than about 0.1% of the amount of dopant atoms in the region 204. In an illustrative example, an amount of dopant atoms outside of the region 204 can be 0.05% to 5% of the amount of dopant atoms in the region 204.

The region 204 can also include a section 210 that is free of dopant atoms. In some cases, the section 210 can be free of the dopant atoms because the portion of the surface 202 corresponding to the section 210 is covered with a patterned material, such as photoresist or an oxide layer. In other cases, the section 210 can be free of the dopant atoms because semiconductor material atoms of the portion of the surface 202 corresponding to the section 210 may have been attached to a molecule that is free of a dopant atom.

FIG. 3 illustrates a cross-sectional view of a portion of a substrate 300 having semiconductor material atoms labeled as “SC” and dopant atoms labeled as “D” disposed in a region of the substrate. The semiconductor material atoms can include silicon, germanium, or a combination thereof. Additionally, the dopant atoms can include a group 15 element. In some cases, the dopant atoms can include arsenic. In other situations, the dopant atoms can include phosphorous.

In a particular embodiment, the substrate 300 includes a surface 302. The surface can include one or more substantially planar portions, such as a first portion 304 and a second portion 306. The surface 302 can also include one or more portions having topographic features, such as a first topographic feature 308 and a second topographic feature 310, that extend from a body 312 of the substrate 300. In an embodiment, the first topographic feature 308 and the second topographic feature 310 can include a fin feature of a semiconductor substrate. In the illustrative embodiment of FIG. 3, the substrate 300 includes a region 314 that includes dopant atoms and semiconductor material atoms. The body 312 includes substantially all semiconductor material atoms. The region 314 can be substantially disposed along a contour of the surface 302, in some embodiments. The dopant atoms can be disposed in the region by one or more of the embodiments described with respect to the process 100 of FIG. 1. In an illustrative embodiment, the region 314 can have a depth 316. The depth 316 can be relative to the surface 302. Although not shown in FIG. 3, portions of the region 314 can be free of dopant atoms due to a patterned material being disposed on the surface 302, such as patterned photoresist or a patterned oxide layer.

In some cases, the depth 316 can be no greater than about 20 nm, no greater than about 16 nm, no greater than about 12 nm, no greater than about 8 nm, or no greater than about 4 nm. In an illustrative example, the depth 316 can be included in a range of about 0.3 nm to about 30 nm. In another illustrative example, the depth can be included in a range of about 2 nm to about 10 nm. In various instances, dopant atoms can be absent from portions outside of the region 314. In an embodiment, an amount of dopant atoms outside of the region 314 can be no greater than about 4% of the amount of dopant atoms in the region 314, no greater than about 2% of the amount of dopant atoms in the region 314, no greater than about 1% of the amount of dopant atoms in the region 314, no greater than about 0.5% of the amount of dopant atoms in the region 314, or no greater than about 0.1% of the amount of dopant atoms in the region 314. In an illustrative example, a amount of dopant atoms outside of the region 314 can be 0.05% to 5% of the amount of dopant atoms in the region 314.

Substrates formed according to embodiments herein may have certain advantages over the state of the art. In particular, substrates formed according to embodiments described herein may have a more uniform distribution of dopant atoms than the distribution provided by conventional processes, such as ion implantation. Additionally, the concentration of the dopant in the substrate can be controlled by using blocking molecules or by using multiple layers of arsenic-containing compounds bonded to atoms of the surface of the substrate. Furthermore, the depth of the diffusion of the dopant atoms can be controlled such that semiconductor devices with ultra-shallow junctions less than 10 nm can be formed. In some cases, the ultra-shallow junctions may be formed due to the decreased damage to the substrate prior to the annealing process, which may limit transient enhanced diffusion that is often present when conventional doping techniques, such as ion implantation or knock-in processes, are utilized.

Although the subject matter has been described in language specific to structural features and/or methodological acts, it is to be understood that the subject matter defined in the appended claims is not necessarily limited to the specific features or acts described. Rather, the specific features and acts are disclosed as exemplary forms of implementing the claims.

The concepts described herein will be further described in the following examples, which do not limit the scope of the disclosure described in the claims.

### EXAMPLES

### Synthesis of Arsenic-Containing Compounds

### Example 1

A composition of matter having the chemical formula:

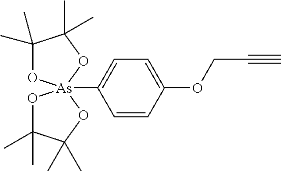

was formed when about 4.323 g of the bis-pinacol adduct of 4-hydroxyphenylarsonic acid was treated with excess potassium carbonate (about 6.39 g) and propargyl bromide (about 5.13 mL, 80% in xylene). Dimethylformamide (DMF) (about 41.5 mL) was added and the heterogeneous mixture was stirred at room temperature (RT) for about 40 hours. Glacial acetic acid (about 35 mL) was added to the heterogeneous mixture. After the evolution of CO₂ ceases, the mixture was diluted with water (about 130 mL) and the off-white small needles were isolated by suction filtration with medium filter paper. The filtrand was washed with water and dried (about 8.95 g, about 89% yield) and then was recrystallized from ethanol. After drying, 5.094 g was isolated. The ethanol supernatant and washings from the recrystallization are combined and treated with water to precipitate additional product. After filtration and drying another 3.218 g of the desired product was recovered.

### Example 2

A composition of matter having the chemical formula:

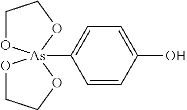

was formed when 4-hydroxyphenylarsonic acid (about 7.257 g) was suspended in ethylene glycol (EG, about 50.9 g) and was heated to about 140° C. under N₂ via an oil bath. After reaching about 140° C., the setpoint was lowered to about 100° C., and that temperature was maintained for about 2 hours. After cooling somewhat, near-colorless crystals separate from the yellow supernatant of the hot reaction mixture, and the product was isolated by suction filtration of the warm reaction mixture without washing. The product was allowed to dry on the suction filter overnight, and subsequent ¹H NMR analysis and weighing showed the product to be free from EG and recovered in good yield.

### Example 3

A composition of matter having the chemical formula:

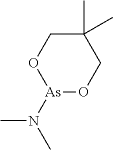

was formed when neopentyl glycol (3.22 g) was added to 60 mL hexane in a 100 mL round-bottom flask; then, under N₂, tris(dimethylamino)arsine (6.74 g) was added dropwise. The mixture was refluxed under N₂ flow for 1.5 hours. Then the reflux condenser was removed, and the temperature of the oil bath was increased to 90° C. to remove the hexane under N₂ flow. Once most of the hexane was removed, the flask was quickly attached to a rotary evaporation system to further remove hexane under reduced pressure at room temperature, yielding 6.6 grams of a transparent, colorless, moisture sensitive liquid.

### Example 4

A composition of matter having the chemical formula:

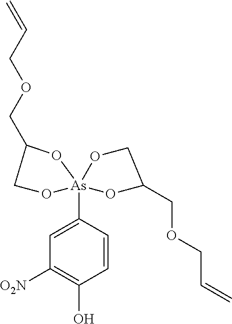

was formed when about 6.1 g of (4-hydroxy-3-nitrophenyl)arsonic acid and about 6.13 g of 3-(alloxy)propane-1,2-diol were suspended in about 60 mL of toluene and heated to reflux with the azeotropic removal of water for about 16 hours. After cooling, the toluene was removed in vacuo to give about 11 g of a substance that includes the composition of matter. The substance appeared as a yellow oil.

### Example 5

A composition of matter having the chemical formula:

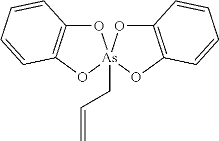

was formed when allylarsonic acid (about 4.067 g, about 24.5 mmol) and catechol (about 5.40 g, about 49 mmol) were refluxed under N₂ overnight in toluene (about 80 mL) with azeotropic removal of water (Dean-Stark trap). After removal of solvent, the resulting tan crystals (about 8.1 g) comprise the desired composition of matter.

### Example 6

A composition of matter having the chemical formula:

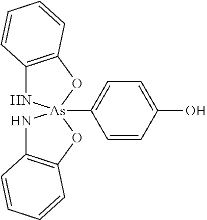

was formed when 4-hydroxyphenylarsonic acid (about 5 g) and 2-aminophenol (about 5 g) were refluxed together in toluene (about 150 mL) with removal of the water that was formed (Dean-Stark trap). The supernatant quickly became very dark green and the product comes out of solution as a spongy yellow mass. After the theoretical amount of water was collected, the desired product was filtered off and was washed with toluene (yield: about 8 g, about 91%).

### Example 7

A composition of matter having the chemical formula:

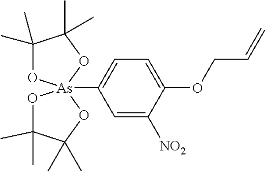

is formed when a portion of the bis-pinacol adduct of roxarsone (about 8.42 g, about 18.9 mmol) was treated with excess cesium carbonate (about 7.4 g, about 22.7 mmol) and allyl bromide (about 2.54 g, about 21 mmol) in dimethylformamide (DMF, about 45 mL) and the heterogeneous mixture was stirred at room temperature overnight. Glacial acetic acid (about 40 mL) was added to the heterogeneous mixture. After the evolution of CO₂ ceases, the mixture was diluted with water (about 130 mL) and the pale yellow powder was isolated on a medium frit and was washed with water. After drying on the frit, the yield was about 8.4 g (about 92%).

### Example 8

A composition of matter having the chemical formula:

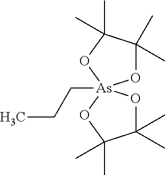

was formed when about 3.36 g of propylarsonic acid and about 4.72 g of pinacol are suspended in about 70 mL of toluene and heated at reflux with azeotropic removal of water overnight. Gravity filtration to remove a small amount of suspension and removal of the toluene in vacuo from the filtrate produced about 7 g of the desired product.

### Example 9

A composition of matter having the chemical formula:

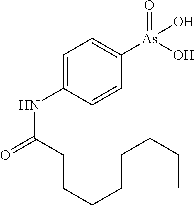

was formed when p-arsanilic acid (about 1.5 g, about 6.91 mmol) was dissolved in absolute ethanol (about 15 mL) and chilled in an ice-water bath with stirring. Nonanoyl chloride (about 1.47 g, about 8.29 mmol) was added dropwise. The mixture was stirred for approximately 4 hours, and enough water was added to precipitate out the powder, which was then filtered by suction, washed with water, and dried overnight. Analysis of the reaction product (¹H NMR, DMSO-d₆) shows it to be the desired compound free from any major impurities, formed in good yield.

### Example 10

A composition of matter having the chemical formula:

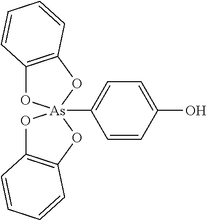

was formed when 4-hydroxyphenylarsonic acid (2.18 g, 10 mmol) and catechol (2.20 g, 20 mmol) were refluxed together in toluene (100 mL) for 4 hours with removal of the water formed (Dean-Stark trap). The hot solution was vacuum filtered through paper, and some crystallization occurs upon filtration. The filtrate was refrigerated for about 1 hour to induce more crystallization. A first crop of the pale yellow crystalline product was collected by suction filtration (2.62 g, 68%). Additional product (0.89 g) was obtained by evaporation of the supernatant. ¹HNMR analysis showed the crystals to contain unreacted phenolarsonic acid (3.8 wt %) and catechol (0.63 wt %) as well as the desired product (95.57 wt %).

### Example 11

A composition of matter having the chemical formula:

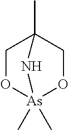

was formed when cacodylic acid (about 3.047 g, about 22 mmol) and 2-amino-2-methyl-1,3-propanediol (about 2.32 g, about 22 mmol) were suspended in toluene (about 60 mL) and heated to reflux with azeotropic removal of water (Dean-Stark trap) under an atmosphere of nitrogen overnight. After cooling, the toluene was removed in vacuo to leave the desired product as an amber oil, recovered in good yield.

### Example 12

A composition of matter having the chemical formula:

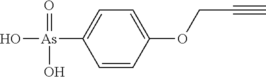

was formed when a the bis ethylene glycol adduct of 4-hydroxyphenylarsonic acid (about 3.5 g, about 12 mmol), propargyl bromide (about 2.75 mL, 80% in toluene, about 25 mmol) and potassium carbonate (about 3.5 g, about 25 mmol) were stirred together in DMF (about 25 mL) at room temperature for about 96 hours. The heterogeneous mixture was diluted with glacial acetic acid (ca 40 mL). Water (about 150 mL) was added in an attempt to precipitate the expected product. A small amount (about 0.5 g) of a colorless, very finely powdered precipitate, which was slow to filter, was isolated and was washed with a little dichloromethane. ¹H NMR analysis shows that the ethylene glycol ligands were lost and the obtained product was the propargyl ether of 4-hydroxyphenylarsonic acid.

### Example 13

A composition of matter having the chemical formula:

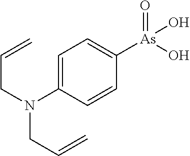

was formed when p-arsanilic acid (2.6 g, 12 mmol) was dissolved in an aqueous solution of sodium carbonate (4.15 g, 39.2 mmol in 60 mL water). Allyl bromide (6.2 g, 51.2 mmol), dichloromethane (10 mL), and tetrabutylammonium bromide (20 mg) were added and the biphasic mixture was stirred for about 64 hours at ambient temperature. More water (about 65 mL) and more dichloromethane (about 20 mL) were added and the mixture was stirred for 1 hour and then was transferred to a 250 mL separatory funnel. The layers are separated and the aqueous layer was washed with additional dichloromethane (3×20 mL). The aqueous layer was acidified to pH 5-6 with careful drop-wise addition of concentrated sulfuric acid to give a nearly colorless, easily-filterable powder. The powder was washed with water (3×20 mL) and allowed to dry on the suction filter overnight. The yield was about 2.68 g, about 75%.

### Example 14

A composition of matter having the chemical formula:

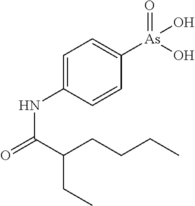

was formed when p-arsanilic acid (about 1.5 g, about 6.91 mmol) was dissolved in absolute ethanol (about 15 mL) and was chilled in an ice-water bath with stirring. 2-Ethylhexanoyl chloride (about 1.35 g, about 8.29 mmol) was added dropwise. The mixture was stirred for approximately 4 hours, and enough water was added to precipitate out the somewhat waxy powder, which was then filtered by suction, washed with water, and dried overnight. Analysis of the reaction product (¹H NMR, DMSO-d₆) shows it to be the desired compound free from any major impurities, formed in good yield.

### Example 15

A composition of matter having the chemical formula:

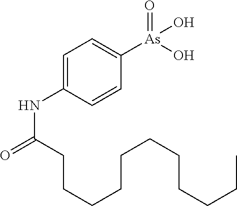

was formed when p-arsanilic acid (about 14.28 g, about 65.8 mmol) was dissolved in absolute ethanol (about 150 mL) and was chilled in an ice-water bath with stirring. Dodecanoyl chloride (lauroyl chloride, about 19 mL, about 17.3 g, about 79 mmol) was added dropwise. The mixture was stirred for approximately 4 hours, and water was added to precipitate out the product, which was then filtered by suction and dried overnight. Analysis of the product of the reaction shows the yield of desired compound to be 51%.

### Example 16

A composition of matter having the chemical formula:

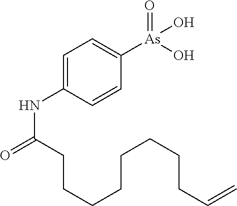

was formed when p-arsanilic acid (about 14.28 g, about 65.8 mmol) was dissolved in absolute ethanol (about 150 mL) and was chilled in an ice-water bath with stirring. 10-Undecenoyl chloride (about 17 mL, about 16 g, about 79 mmol) was added dropwise. The mixture was stirred for approximately 4 hours, and water was added to precipitate out the product, which was then filtered by suction and dried overnight. Analysis of the product of the reaction shows the yield of desired compound to be about 87%.

### Arsenic Doping Examples

Solvents were typically used as received, but when used with moisture-sensitive compounds, particularly tris(dimethylamino)arsine, tetraglyme was dried in a rotary evaporator. A typical 500 mL aliquot of solvent was dried in the rotary evaporator for 6 hours, at 75° C. and 120 rpm, under a vacuum of 5-10 Torr. The water content was usually reduced to a level below 200 ppm, as determined by Karl Fischer titration.

Experiments were performed using undoped, intrinsic silicon (100) wafers, unless otherwise stated. In a few cases intrinsic Ge (100) coupons were also included. The wafers were cleaved into coupons about 2 cm² in size. Typically two (and sometimes more) coupons were used in a single run.

The coupons were first immersed in 0.5% hydrofluoric acid for 2 minutes, and then rinsed with ultrapure (18 MΩ) water. This process removes the native oxide layer on the surface, and leaves a hydrogen terminated silicon surface. Once the coupons were dried using a stream of nitrogen, they were placed in the reaction vessel.

The glass reaction vessel has a flat bottom surface. The lid is sealed to the vessel body by means of a silicone-coated PTFE O-ring and a clamp. The lid has 3 necks, through which are inserted a nitrogen inlet line to sparge the vessel, an outlet connected to a bubbler, and a thermocouple. The vessel is heated with a heating mantle connected to a PID controller.

Once the coupons and the dopant solution were added to the sparged vessel, the vessel was heated to the desired temperature for a given time. At the end of the reaction time, the heat was turned off, and the coupons were removed from the (still hot) solution. For some dopants, the coupons were rinsed in a beaker of hot solvent (the same solvent as used for the reaction) for 20 seconds. For other dopants, this step was not necessary and not used. All coupons were then rinsed with isopropanol at room temperature and blown dry with nitrogen. Some coupons still had a hazy surface at this point. The haze was typically removed by sonication in tetraglyme at 20° C. for a few minutes, followed by rinsing with isopropanol and drying with nitrogen.

After processing, coupons were analyzed using secondary ion mass spectrometry (SIMS).

Table 1 of the Detailed Description lists the arsenic dopants that were used. Table 3 lists the solvents that were used. Reactions were performed as described in the Experimental section above. Table 4 lists the reaction conditions for each experiment number (exp. no.) (dopant, solvent, concentration of dopant, temperature, and time at the given temperature), as well as the arsenic dose measured by SIMS. No further processing (i.e. no capping or annealing) was performed between the solution monolayer doping (MLD) processing and the SIMS analysis.

TABLE 3
List of solvents used.

| | | | Flash Point |
|---|---|---|---|
| Solvent # | Name | Structure | (° C.) |
| S1 | Tetraglyme | 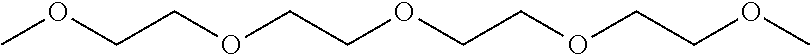 | 141 |
| S2 | DMSO | 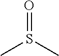 | 85 |
| S8 | Mesitylene | 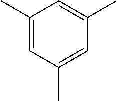 | 53 |
| S9 | Water | H₂O | NA |
| S10 | DB Acetate (old bottle with significant impurities) | 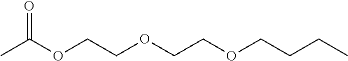 | — |
| S12 | DB Acetate (pure) | 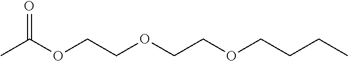 | 116 |
| S13 | Eastman DB Solvent | 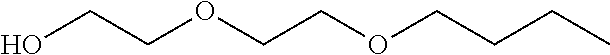 | 111 |
| S14 | N-Methylpyrrolidone | 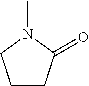 | 91 |

TABLE 4
Results of arsenic MLD. The arsenic dose was measured by
SIMS after treatment of the Si coupon with a dopant solution
as listed, without doing any capping or annealing.

| | | | | | | Dose | |
|---|---|---|---|---|---|---|---|
| Exp. | Dop- | Sol- | Conc. | Time | Temp. | (atoms/ | |
| No. | ant | vent | (%) | (min) | (° C.) | cm2) | Note |
| 1 | — | — | — | — | — | 6.18E+10 | Unprocessed |
| | | | | | | | control |
| 2 | — | — | — | — | — | 6.99E+10 | Unprocessed |
| | | | | | | | control |
| 3 | — | — | — | — | — | 3.63E+11 | Unprocessed |
| | | | | | | | control |
| 4 | 1 | 1 | 5 | 150 | 120 | 1.38E+14 | Standard |
| | | | | | | | condition |
| 5 | 1 | 1 | 5 | 150 | 120 | 1.61E+14 | |
| 6 | 1 | 1 | 5 | 150 | 120 | 1.60E+14 | |
| 7 | 1 | 1 | 5 | 150 | 120 | 9.12E+13 | |
| 8 | 1 | 1 | 5 | 150 | 120 | 1.67E+14 | |
| 9 | 1 | 1 | 5 | 150 | 120 | 1.82E+14 | |
| 10 | 1 | 1 | 5 | 150 | 120 | 1.05E+14 | |
| 11 | 1 | 1 | 5 | 150 | 120 | 1.36E+14 | |
| 12 | 1 | 1 | 5 | 150 | 120 | 1.54E+14 | |
| 13 | 1 | 1 | 5 | 150 | 120 | 1.28E+14 | |
| 14 | 1 | 1 | 5 | 150 | 120 | 1.02E+14 | |
| 15 | 1 | 1 | 5 | 150 | 120 | 8.66E+13 | |
| 16 | 1 | 1 | 1 | 150 | 120 | 1.49E+13 | |
| 17 | 1 | 1 | 5 | 60 | 120 | 4.24E+13 | |
| 18 | 1 | 1 | 5 | 60 | 120 | 4.87E+13 | |
| 19 | 1 | 1 | 5 | 30 | 120 | 5.12E+13 | |
| 20 | 1 | 1 | 5 | 30 | 120 | 5.22E+13 | |
| 21 | 1 | 1 | 5 | 15 | 120 | 3.70E+13 | |
| 22 | 1 | 1 | 5 | 15 | 120 | 3.28E+13 | |
| 23 | 1 | 1 | 5 | 15 | 120 | 8.11E+13 | |
| 24 | 1 | 1 | 5 | 15 | 120 | 6.72E+13 | |
| 25 | 1 | 1 | 5 | 150 | 100 | 3.29E+13 | |
| 26 | 1 | 1 | 5 | 150 | 100 | 3.03E+13 | |
| 27 | 1 | 1 | 5 | 150 | 80 | 1.93E+13 | |
| 28 | 1 | 1 | 5 | 150 | 80 | 2.46E+13 | |
| 29 | 1 | 1 | 5 | 150 | 60 | 1.92E+13 | |
| 30 | 1 | 1 | 5 | 150 | 60 | 2.46E+13 | |
| 31 | 1 | 1 | 5 | 150 | 120 | 8.77E+13 | No sparging |
| 32 | 1 | 1 | 5 | 150 | 120 | 7.49E+13 | No sparging |
| 33 | 1 | 1 | 5 | 150 | 120 | 9.04E+13 | No sparging |
| | | | | | | | but with |
| | | | | | | | stirring |
| 34 | 1 | 1 | 5 | 150 | 120 | 8.05E+13 | No sparging |
| | | | | | | | but with |
| | | | | | | | stirring |
| 35 | 1 | 1 | 5 | 150 | 120 | 1.23E+14 | 2 MLD |
| | | | | | | | treatments, |
| | | | | | | | back to back |
| 36 | 1 | 1 | 5 | 150 | 120 | 1.73E+14 | 2 MLD |
| | | | | | | | treatments, |
| | | | | | | | back to back, |
| | | | | | | | with |
| | | | | | | | exposure to |
| | | | | | | | water in |
| | | | | | | | between |
| 37 | 1 | 2 | 5 | 150 | 120 | 8.95E+13 | |
| 38 | 1 | 2 | 5 | 150 | 120 | 8.46E+13 | |
| 39 | 1 | 12 | 5 | 150 | 100 | 2.08E+14 | |
| 40 | 1 | 12 | 5 | 150 | 120 | 1.92E+14 | |
| 41 | 3 | 1 | 1 | 150 | 120 | 9.99E+13 | |
| 42 | 3 | 1 | 2 | 150 | 120 | 8.01E+13 | |
| 43 | 3 | 2 | 5 | 150 | 120 | 1.95E+13 | |
| 44 | 3 | 2 | 5 | 150 | 120 | 2.50E+13 | |
| 45 | 4 | 12 | 1 | 150 | 110 | 1.34E+14 | |
| 46 | 4 | 12 | 1 | 150 | 110 | 2.05E+14 | |
| 47 | 4 | 13 | 1 | 150 | 100 | 4.45E+13 | |
| 48 | 4 | 12 & 13 | 1 | 150 | 100 | 7.33E+13 | 50/50 blend |
| | | | | | | | of solvents |
| | | | | | | | 12 and 13 |
| 49 | 4 | 12 & 13 | 1 | 150 | 100 | 6.75E+13 | 75/25 blend |
| | | | | | | | of solvents |
| | | | | | | | 12 and 13 |
| 50 | 4 | 9 | 1 | 150 | 90 | 9.97E+12 | Aqueous |
| | | | | | | | solution |
| 51 | 8 | 12 | 1 | 150 | 110 | 1.60E+14 | |
| 52 | 9 | 2 | 5 | 150 | 100 | 4.34E+13 | |
| 53 | 9 | 2 | 5 | 150 | 100 | 4.11E+13 | |
| 54 | 10 | 1 | 5 | 150 | 120 | 2.73E+13 | |
| 55 | 10 | 1 | 5 | 150 | 120 | 2.50E+13 | |
| 56 | 11 | 1 | 5 | 150 | 120 | 1.71E+14 | |
| 57 | 11 | 1 | 5 | 150 | 120 | 1.87E+14 | |
| 58 | 11 | 1 | 5 | 150 | 120 | 1.02E+14 | |
| 59 | 11 | 1 | 5 | 150 | 120 | 1.13E+14 | |
| 60 | 11 | 1 | 5 | 150 | 120 | 1.33E+14 | |
| 61 | 11 | 1 | 5 | 150 | 120 | 1.39E+14 | No HF |
| | | | | | | | treatment to |
| | | | | | | | remove |
| | | | | | | | native oxide |
| 62 | 11 | 1 | 5 | 30 | 120 | 6.84E+13 | |
| 63 | 11 | 1 | 5 | 30 | 80 | 1.58E+13 | |
| 64 | 11 | 1 | 0.5 | 15 | 80 | 1.23E+13 | |
| 65 | 11 | 2 | 5 | 150 | 100 | 8.59E+13 | |
| 66 | 11 | 2 | 5 | 150 | 100 | 8.22E+13 | |
| 67 | 12 | 1 | 5 | 150 | 120 | 1.07E+14 | |
| 68 | 12 | 1 | 5 | 150 | 120 | 1.15E+14 | |
| 69 | 12 | 1 | 5 | 150 | 120 | 9.73E+13 | |
| 70 | 12 | 1 | 5 | 150 | 120 | 7.17E+13 | Solution was |
| | | | | | | | heated at |
| | | | | | | | 120° C. |
| | | | | | | | for 7 days |
| | | | | | | | before use |
| 71 | 12 | 1 | 5 | 30 | 120 | 2.19E+14 | |
| 72 | 12 | 1 | 5 | 30 | 80 | 3.12E+14 | |
| 73 | 12 | 2 | 5 | 150 | 100 | 1.10E+14 | |
| 74 | 12 | 2 | 5 | 150 | 100 | 1.05E+14 | |
| 75 | 14 | 2 | 5 | 150 | 120 | 3.41E+13 | |
| 76 | 14 | 2 | 5 | 150 | 120 | 2.70E+13 | |
| 77 | 15 | 1 | 5 | 150 | 120 | 5.16E+13 | |
| 78 | 15 | 1 | 5 | 150 | 120 | 4.36E+13 | |
| 79 | 15 | 1 | 3 | 150 | 120 | 1.25E+14 | |
| 80 | 15 | 1 | 3 | 150 | 120 | 1.04E+14 | |
| 81 | 15 | 1 | 1 | 150 | 120 | 2.96E+13 | |
| 82 | 15 | 1 | 1 | 150 | 120 | 2.87E+13 | |
| 83 | 15 | 1 | 3 | 15 | 120 | 4.04E+13 | |
| 84 | 15 | 1 | 3 | 15 | 120 | 3.99E+13 | |
| 85 | 15 | 1 | 3 | 150 | 140 | 3.87E+13 | |
| 86 | 15 | 1 | 3 | 150 | 140 | 3.18E+13 | |
| 87 | 15 | 1 | 0.5 | 15 | 80 | 1.89E+13 | |
| 88 | 15 | 1 | 5 | 150 | 120 | 3.58E+13 | Multiday run |
| | | | | | | | with same |
| | | | | | | | solution - |
| | | | | | | | day 1 |
| 89 | 15 | 1 | 5 | 150 | 120 | 2.69E+13 | Multiday run |
| | | | | | | | with same |
| | | | | | | | solution - |
| | | | | | | | day 2 |
| 90 | 15 | 1 | 5 | 150 | 120 | 3.38E+13 | Multiday run |
| | | | | | | | with same |
| | | | | | | | solution - |
| | | | | | | | day 3 |
| 91 | 15 | 1 | 5 | 150 | 120 | 4.11E+13 | Multiday run |
| | | | | | | | with same |
| | | | | | | | solution - |
| | | | | | | | day 4 |
| 92 | 15 | 1 | 5 | 150 | 120 | 1.59E+14 | Multiday run |
| | | | | | | | with same |
| | | | | | | | solution - |
| | | | | | | | day 5 |
| 93 | 15 | 8 | 5 | 150 | 90 | 2.50E+13 | |
| 94 | 16 | 2 | 5 | 150 | 120 | 5.61E+12 | |
| 95 | 16 | 2 | 5 | 150 | 120 | 5.92E+12 | |
| 96 | 17 | 1 | 5 | 150 | 120 | 1.10E+14 | |
| 97 | 17 | 1 | 5 | 150 | 120 | 7.96E+13 | |
| 98 | 17 | 1 | 5 | 150 | 120 | 1.02E+14 | |
| 99 | 17 | 1 | 5 | 150 | 120 | 8.59E+13 | |
| 100 | 17 | 1 | 5 | 150 | 80 | 2.97E+13 | |
| 101 | 17 | 1 | 5 | 30 | 120 | 1.02E+14 | |
| 102 | 17 | 1 | 5 | 30 | 80 | 8.03E+13 | |
| 103 | 17 | 2 | 5 | 150 | 100 | 1.14E+13 | |
| 104 | 17 | 2 | 5 | 150 | 100 | 1.10E+13 | |
| 105 | 18 | 1 | 5 | 150 | 120 | 1.66E+14 | |
| 106 | 18 | 1 | 5 | 150 | 120 | 1.73E+14 | |
| 107 | 19 | 1 | 4 | 150 | 120 | 3.79E+14 | |
| 108 | 19 | 1 | 4 | 150 | 120 | 3.90E+14 | |
| 109 | 19 | 1 | 5 | 150 | 120 | 3.04E+14 | |
| 110 | 19 | 1 | 5 | 150 | 120 | 2.52E+14 | |
| 111 | 19 | 8 | 5 | 150 | 120 | 1.10E+15 | |
| 112 | 19 | 8 | 5 | 150 | 120 | 1.14E+15 | |
| 113 | 20 | 1 | 6 | 150 | 120 | 2.25E+14 | |
| 114 | 20 | 1 | 6 | 150 | 120 | 2.29E+14 | |
| 115 | 20 | 1 | 6 | 150 | 120 | 1.45E+14 | |
| 116 | 20 | 1 | 6 | 150 | 120 | 1.56E+14 | |
| 117 | 20 | 1 | 5 | 150 | 120 | 2.07E+14 | |
| 118 | 20 | 1 | 5 | 30 | 120 | 1.62E+14 | |
| 119 | 20 | 1 | 5 | 30 | 80 | 1.38E+14 | |
| 120 | 21 | 1 | 5 | 150 | 120 | 7.16E+13 | |
| 121 | 21 | 1 | 5 | 150 | 120 | 7.16E+13 | |
| 122 | 22 | 1 | 5 | 150 | 120 | 8.31E+13 | |
| 123 | 23 | 1 | 5 | 150 | 120 | 7.26E+13 | |
| 124 | 24 | 1 | 5 | 150 | 120 | 5.81E+14 | |
| 125 | 24 | 1 | 5 | 150 | 120 | 1.76E+14 | |
| 126 | 24 | 1 | 5 | 30 | 120 | 1.35E+14 | |
| 127 | 25 | 1 | 5 | 150 | 120 | 5.70E+13 | |
| 128 | 26 | 1 | 5 | 150 | 120 | 9.47E+13 | |
| 129 | 27 | 1 | 5 | 150 | 120 | 2.22E+14 | |
| 130 | 28a | 1 | 1 | 150 | 120 | 2.37E+14 | 28a - |
| | | | | | | | obtained |
| | | | | | | | from City |
| | | | | | | | Chemical |
| 131 | 28a | 1 | 1 | 15 | 120 | 2.98E+14 | |
| 132 | 28a | 1 | 1 | 150 | 80 | 3.00E+14 | |
| 133 | 28a | 1 | 1 | 15 | 80 | 2.03E+14 | |
| 134 | 28a | 1 | 1 | 15 | 80 | 2.30E+13 | No HF |
| | | | | | | | pretreatment |
| 135 | 28b | 1 | 1 | 150 | 120 | 7.71E+13 | 28b - |
| | | | | | | | obtained |
| | | | | | | | from TCI |
| 136 | 28b | 1 | 1 | 150 | 120 | 4.28E+13 | |
| 137 | 28b | 1 | 1 | 150 | 120 | 7.58E+13 | |
| 138 | 28b | 1 | 1 | 150 | 120 | 7.41E+13 | |
| 139 | 28b | 1 | 1 | 150 | 120 | 7.81E+13 | |
| 140 | 28b | 1 | 1 | 150 | 120 | 8.03E+13 | |
| 141 | 28b | 1 | 1 | 150 | 120 | 1.04E+14 | |
| 142 | 28b | 1 | 2 | 150 | 120 | 1.11E+14 | |
| 143 | 28b | 1 | 2 | 150 | 120 | 1.12E+14 | |
| 144 | 28b | 1 | 3 | 150 | 120 | 4.35E+13 | |
| 145 | 28b | 1 | 3 | 150 | 120 | 1.07E+14 | |
| 146 | 28b | 1 | 1 | 15 | 120 | 1.19E+14 | |
| 147 | 28b | 1 | 2 | 15 | 120 | 1.14E+14 | |
| 148 | 28b | 1 | 0.5 | 15 | 120 | 1.04E+14 | |
| 149 | 28b | 1 | 1 | 15 | 120 | 1.16E+14 | |
| 150 | 28b | 1 | 1 | 15 | 120 | 6.46E+13 | |
| 151 | 28b | 1 | 1 | 15 | 120 | 7.25E+13 | |
| 152 | 28b | 1 | 1 | 150 | 80 | 9.16E+13 | |
| 153 | 28b | 1 | 1 | 150 | 80 | 1.28E+14 | |
| 154 | 28b | 1 | 1 | 150 | 80 | 6.52E+13 | |
| 155 | 28b | 1 | 1 | 150 | 120 | 2.47E+14 | 0.1% HCl |
| | | | | | | | added |
| 156 | 28b | 1 | 1 | 15 | 120 | 9.38E+13 | 0.3% HCl |
| | | | | | | | added |
| 157 | 28b | 1 | 1 | 15 | 120 | 1.01E+14 | 0.05% |
| | | | | | | | hydro- |
| | | | | | | | quinone |
| | | | | | | | added |
| 158 | 28b | 1 | 1 | 15 | 120 | 1.33E+14 | 0.1% nitric |
| | | | | | | | acid added |
| 159 | 28b | 1 | 1 | 15 | 120 | 1.56E+14 | 0.1% water |
| | | | | | | | added |
| 160 | 28b | 1 | 1 | 15 | 120 | 1.35E+14 | 0.1% AIBN |
| | | | | | | | added |
| 161 | 28b | 1 | 1 | 15 | 120 | 1.18E+14 | 0.1% oxalic |
| | | | | | | | acid added |
| 162 | 28b | 1 | 1 | 15 | 120 | 4.54+13 | 0.1% benzo- |
| | | | | | | | quinone |
| | | | | | | | added |
| 163 | 28b | 1 | 1 | 15 | 120 | 1.02E+14 | 0.25% |
| | | | | | | | H2SO4 |
| | | | | | | | added |
| 164 | 28b | 1 | 1 | 15 | 120 | 1.41E+14 | 28b exposed |
| | | | | | | | to x-rays in |
| | | | | | | | XRF |
| | | | | | | | instrument |
| | | | | | | | prior to use |
| 165 | 28a | 9 | 1 | 150 | 90 | 1.79E+13 | Aqueous |
| | | | | | | | solution |
| 166 | 32 | 1 | 1 | 150 | 120 | 1.20E+14 | |
| 167 | 32 | 12 | 1 | 150 | 120 | 2.08E+14 | |
| 168 | 33 | 1 | 1 | 150 | 120 | 5.74E+13 | |
| 169 | 34 | 14 | 3 | 150 | 120 | 2.60E+13 | |
| 170 | 35 | 1 | 5 | 150 | 120 | 1.89E+14 | |
| 171 | 35 | 12 | 5 | 150 | 110 | 1.83E+14 | |
| 172 | 35 | 12 | 5 | 150 | 110 | 2.14E+14 | |
| 173 | 35 | 12 | 1 | 150 | 110 | 1.91E+14 | |
| 174 | 35 | 12 | 1 | 15 | 110 | 1.98E+14 | |
| 175 | 35 | 12 | 1 | 15 | 110 | 1.91E+14 | |
| 176 | 35 | 12 | 1 | 15 | 110 | 1.01E+14 | |
| 177 | 35 | 12 | 1 | 15 | 110 | 7.81E+13 | No HF |
| | | | | | | | pretreatment |
| 178 | 35 | 12 | 1 | 15 | 80 | 1.46E+14 | |
| 179 | 36 | 12 | 5 | 15 | 110 | 2.57E+14 | |
| 180 | 36 | 12 | 1 | 15 | 110 | 2.22E+14 | |
| 181 | 36 | 12 | 1 | 15 | 110 | 1.70E+14 | |
| 182 | 36 | 12 | 1 | 15 | 110 | 2.01E+14 | |
| 183 | 36 | 12 | 1 | 15 | 110 | 2.46E+14 | |
| 184 | 36 | 12 | 1 | 15 | 110 | 2.23E+14 | |
| 185 | 36 | 12 | 1 | 15 | 130 | 4.28E+14 | |
| 186 | 36 | 12 | 1 | 15 | 80 | 3.36E+14 | |
| 187 | 36 | 12 | 1 | 15 | 20 | 8.62E+12 | |
| 188 | 36 | 12 | 1 | 10 | 110 | 3.12E+14 | |
| 189 | 36 | 12 | 1 | 10 | 110 | 3.38E+14 | |
| 190 | 36 | 12 | 1 | 5 | 110 | 2.56E+14 | |
| 191 | 36 | 12 | 1 | 60 | 130 | 2.91E+14 | |
| 192 | 36 | 12 | 1 | 60 | 130 | 2.48E+14 | |
| 193 | 36 | 12 | 1 | 60 | 110 | 4.31E+14 | |
| 194 | 36 | 12 | 1 | 60 | 110 | 4.54E+14 | |
| 195 | 36 | 12 | 1 | 60 | 110 | 3.56E+14 | |
| 196 | 36 | 12 | 1 | 60 | 110 | 2.98E+14 | |
| 197 | 36 | 12 | 1 | 60 | 110 | 3.69E+14 | |
| 198 | 36 | 12 | 1 | 60 | 110 | 3.46E+14 | |
| 199 | 36 | 12 | 1 | 60 | 110 | 3.16E+14 | |
| 200 | 36 | 12 | 1 | 60 | 110 | 3.19E+14 | |
| 201 | 36 | 12 | 1 | 60 | 80 | 2.08E+14 | |
| 202 | 36 | 12 | 1 | 60 | 80 | 2.42E+14 | |
| 203 | 36 | 12 | 0.7 | 15 | 110 | 2.71E+14 | |
| 204 | 36 | 12 | 0.6 | 15 | 110 | 2.07E+14 | |
| 205 | 36 | 12 | 0.1 | 5 | 50 | 1.36E+14 | |
| 206 | 36 | 12 | 0.1 | 15 | 50 | 1.99E+14 | |
| 207 | 36 | 12 | 0.1 | 60 | 50 | 2.49E+14 | |
| 208 | 36 | 12 | 0.1 | 60 | 60 | 2.40E+14 | |
| 209 | 36 | 12 | 0.1 | 2 | 70 | 1.09E+14 | |
| 210 | 36 | 12 | 0.1 | 5 | 70 | 2.17E+14 | |
| 211 | 36 | 12 | 0.1 | 10 | 70 | 2.19E+14 | |
| 212 | 36 | 12 | 0.1 | 15 | 70 | 2.87E+14 | |
| 213 | 36 | 12 | 0.1 | 30 | 70 | 2.52E+14 | |
| 214 | 36 | 12 | 0.1 | 60 | 70 | 3.35E+14 | |
| 215 | 36 | 12 | 0.1 | 5 | 80 | 2.55E+14 | |
| 216 | 36 | 12 | 0.1 | 15 | 80 | 3.00E+14 | |
| 217 | 36 | 12 | 0.1 | 60 | 80 | 3.21E+14 | |
| 218 | 36 | 12 | 0.1 | 60 | 110 | 4.24E+14 | |
| 219 | 36 | 12 | 0.1 | 60 | 110 | 4.59E+14 | |
| 220 | 36 | 12 | 0.01 | 60 | 110 | 2.87E+14 | |
| 221 | 36 | 12 | 0.01 | 5 | 70 | 7.32E+13 | |
| 222 | 36 | 12 | 0.01 | 15 | 70 | 2.17E+14 | |
| 223 | 36 | 12 | 0.01 | 60 | 70 | 2.35E+14 | |
| 224 | 37 | 9 | 1 | 30 | 95 | 4.86E+12 | Aqueous |
| | | | | | | | solution |
| 225 | 38 | 12 | 1 | 60 | 110 | 4.26E+14 | |

(Note: for dopant 36, the concentration listed is the concentration of triethylarsenate added.)

Table 5 shows results of arsenic MLD on silicon coupons of different orientations. The arsenic dose was measured by SIMS after treatment of the Si coupon with a dopant solution as listed, without doing any capping or annealing. Table 6 shows results of arsenic MLD on Ge (100) coupons, with Si (100) coupons in the same run for comparison. The arsenic dose was measured by SIMS after treatment of the Ge or Si coupon with a dopant solution as listed, without doing any capping or annealing.

TABLE 5

| | | | | | | Dose | |
|---|---|---|---|---|---|---|---|
| Exp. | | | Conc. | Time | Temp. | (atoms/ | |
| No. | Dopant | Solvent | (%) | (min) | (° C.) | cm²) | Note |
| 226 | 36 | 12 | 1 | 15 | 110 | 3.62E+14 | Si (100) |
| | | | | | | | coupon |
| 227 | 36 | 12 | 1 | 15 | 110 | 3.08E+14 | Si (110) |
| | | | | | | | coupon |
| 228 | 36 | 12 | 1 | 15 | 110 | 3.18E+14 | Si (111) |
| | | | | | | | coupon |

(Note: for dopant36, the concentration listed is the concentration of triethylarsenate added.)

TABLE 6

| Exp. | | | Conc. | Time | Temp. | Dose on Ge | Dose on Si | |
|---|---|---|---|---|---|---|---|---|
| No. | Dopant | Solvent | (%) | (min) | (° C.) | (atoms/cm²) | (atoms/cm²) | Comment |
| 229 | 1 | 1 | 5 | 150 | 120 | 2.11E+14 | 1.23E+14 | 2 MLD |
| | | | | | | | | treatments, |
| | | | | | | | | back to back |
| 230 | 4 | 10 | 1 | 150 | 100 | 1.27E+14 | 2.93E+14 | |
| 231 | 28a | 10 | 1 | 150 | 120 | 5.38E+14 | 2.61E+14 | |
| 232 | 28a | 1 | 1 | 15 | 80 | 1.52E+14 | 2.03E+14 | |
| 233 | 36 | 12 | 1 | 60 | 110 | 1.62E+15 | 3.46E+14 | |
| 234 | 36 | 12 | 1 | 60 | 110 | 5.82E+14 | 3.19E+14 | |

(Note: for dopant 36, the concentration listed is the concentration of triethylarsenate added.)

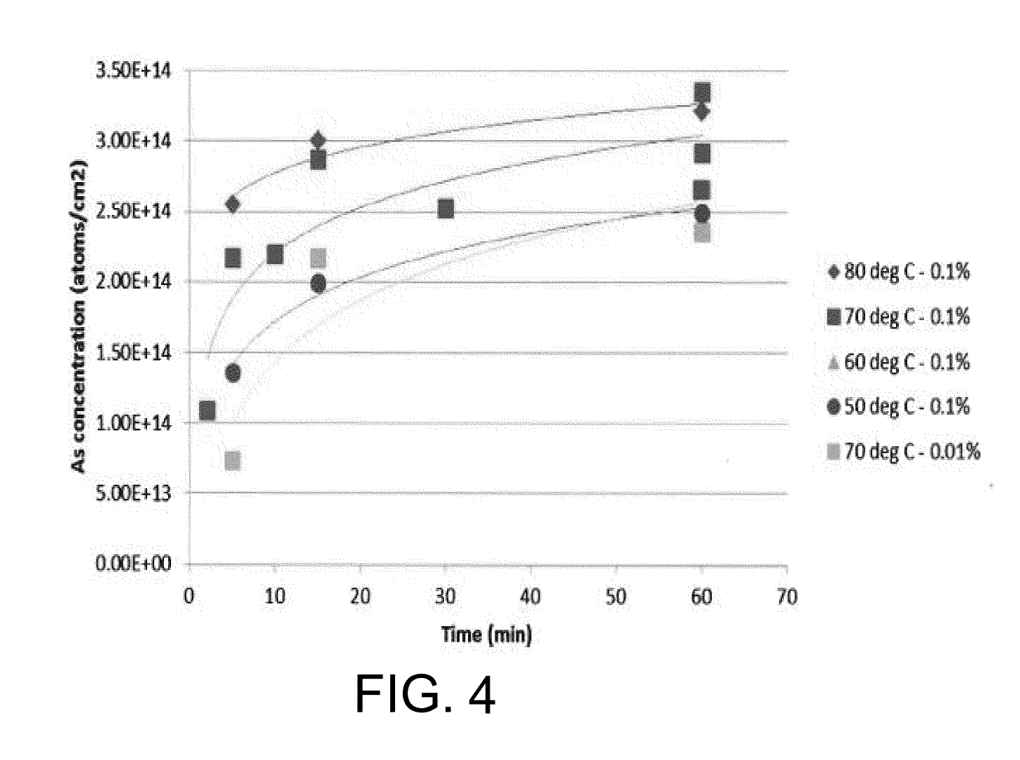

FIG. 4 includes a first graph showing changes in concentration of arsenic atoms attached to atoms at a surface of a substrate that include a semiconductor material as a function of time according to different temperatures and different concentrations of arsenic-containing molecules in a dopant solution. In particular, FIG. 4 shows results using D36 (arsenic acid) as the dopant and S12 (DB Acetate) as the solvent in the dopant solution. For a given set of conditions, increasing the time results in increased arsenic atoms attached to the silicon surface. Additionally, increasing the temperature results in increased arsenic atoms attached to the silicon surface. Increasing the concentration of D36 also results in increased arsenic-containing molecules binding to the silicon surface.

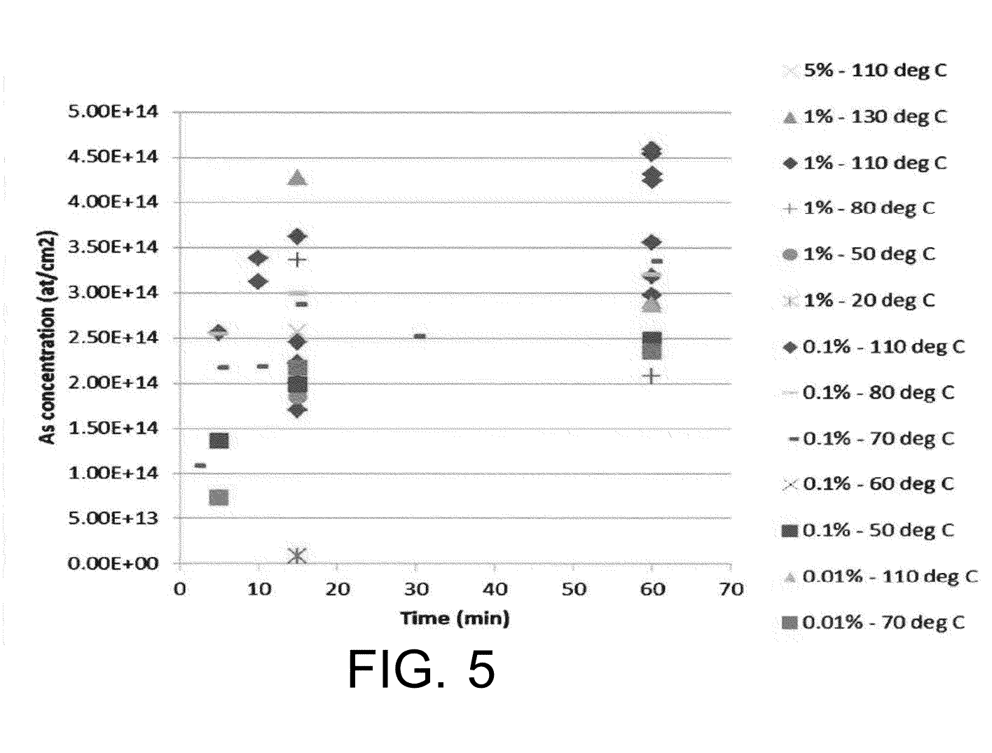

FIG. 5 includes a second graph showing changes in concentration of arsenic atoms attached to atoms of a surface of a substrate that includes a semiconductor material as a function of time according to different temperatures and different concentrations of arsenic-containing molecules in a dopant solution. FIG. 5 shows results using D36 (arsenic acid) as the dopant and S12 (DB Acetate) as the solvent in the dopant solution. The graph generally shows that increasing the reaction time results in increased binding of arsenic atoms to atoms of the silicon surface.

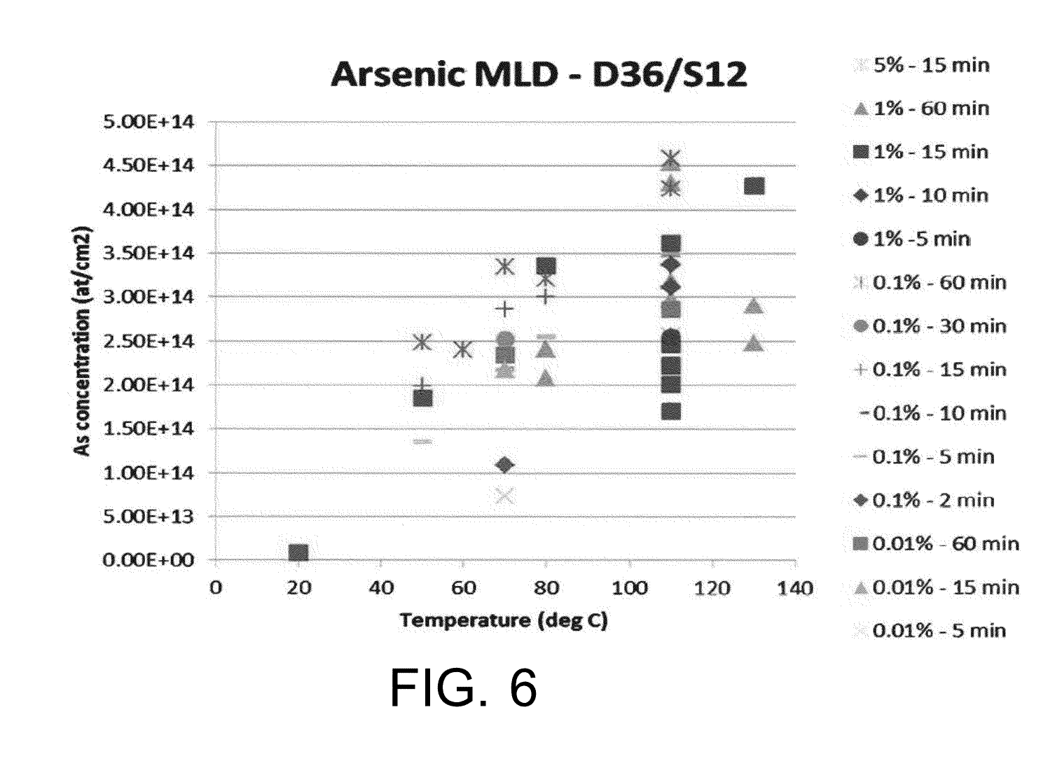

FIG. 6 includes a third graph showing changes in concentration of arsenic atoms attached to atoms of a surface of a substrate that includes a semiconductor material as a function of temperature according to different times of contact between the substrate and a dopant solution and different concentrations of arsenic-containing molecules in the dopant solution. FIG. 6 shows results using D36 (arsenic acid) as the dopant and S12 (DB Acetate) as the solvent in the dopant solution. The graph generally shows that increasing the reaction temperature results in increased binding of arsenic-containing molecules to atoms of the silicon surface.

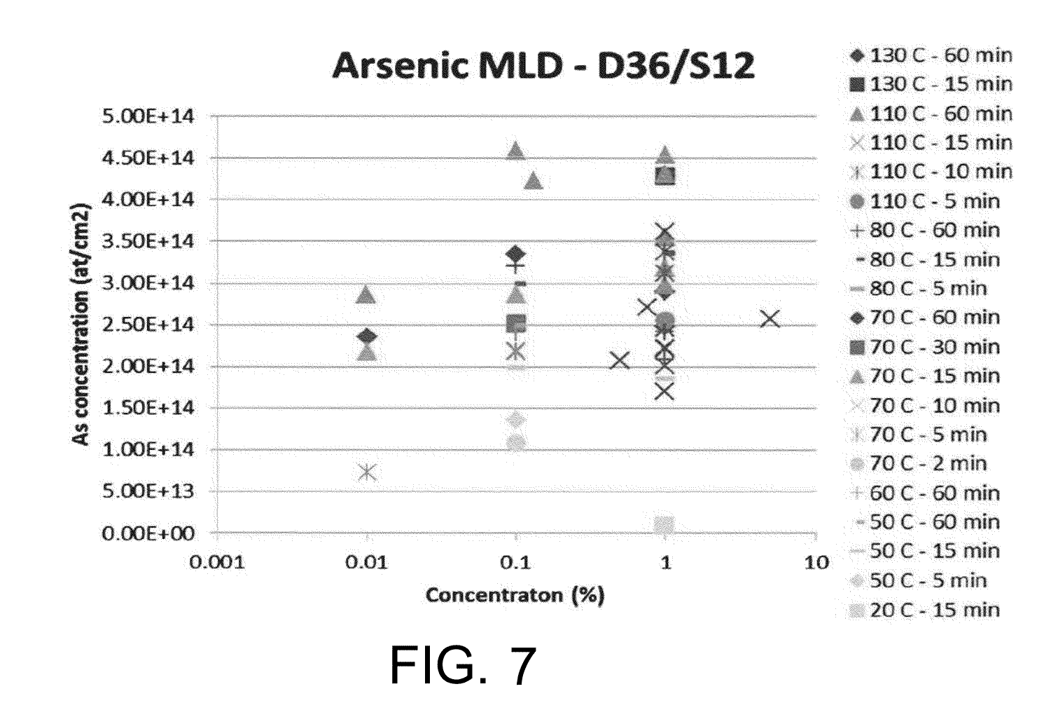

FIG. 7 includes a fourth graph showing changes in concentration of arsenic atoms attached to atoms of a surface of a substrate that includes a semiconductor material as a function of concentration according to different times of contact between the substrate and a dopant solution at different temperatures. FIG. 7 shows results using D36 (arsenic acid) as the dopant and S12 (DB Acetate) as the solvent in the dopant solution. The graph generally shows that increasing the dopant concentration from about 0.01% to about 0.1% results in an increase in binding of arsenic atoms to the silicon surface. For a given set of conditions, increasing the dopant concentration from about 0.1% to about 1% results in less of an increase in the binding of arsenic atoms to the silicon surface.

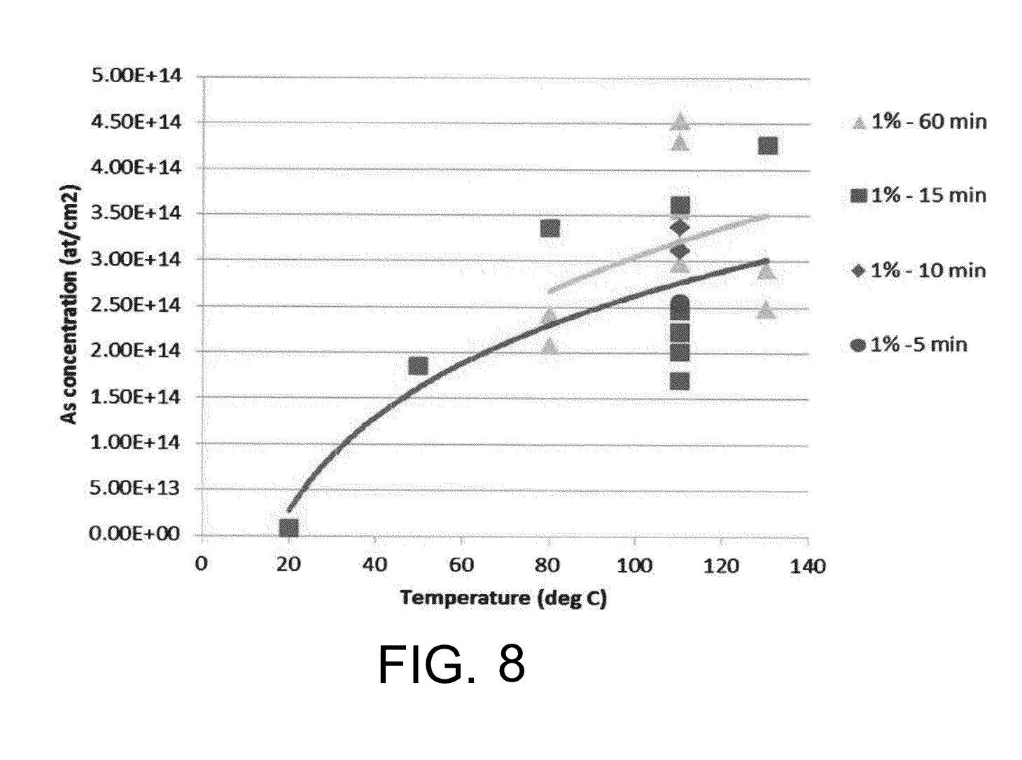

FIG. 8 includes a fifth graph showing changes in concentration of arsenic-containing molecules bonded to atoms of a surface of a substrate that includes a semiconductor material as a function of temperature according to different times of contact between the substrate and a dopant solution and the dopant solution having the same concentration of arsenic-containing molecules for each of the times of contact. FIG. 8 shows results using D36 (arsenic acid) as the dopant and S12 (DB Acetate) as the solvent in the dopant solution with the concentration of D36 being about 1%. The graph generally shows that increasing the reaction temperature results in increased binding of arsenic-containing molecules to atoms of the silicon surface.

A number of phosphorus compounds were also screened as MLD dopants. Table 2 of the Detailed Description lists the phosphorus dopants that were used. The solvents are listed in Table 3 above. Reactions were performed as described in the Experimental section above. Table 7 lists the reaction conditions for each experiment number (exp. no.) (dopant, solvent, concentration of dopant, temperature, and time at the given temperature), as well as the phosphorus dose measured by SIMS. No further processing (i.e. no capping or annealing) was performed between the solution MLD processing and the SIMS analysis.

TABLE 7
Results of phosphorus MLD. The phosphorus dose was measured
by SIMS after treatment of the Si coupon with a dopant solution
as listed, without doing any capping or annealing.

| | | | | | | Dose | |
|---|---|---|---|---|---|---|---|
| Exp. | | | Conc. | Time | Temp. | (atoms/ | |
| No. | Dopant | Solvent | (%) | (min) | (° C.) | cm²) | Notes |
| 235 | P1 | 1 | 4 | 150 | 120 | 2.58E+12 | |
| 236 | P1 | 12 | 5 | 150 | 100 | 2.26E+12 | |
| 237 | P1 | 12 | 1 | 150 | 100 | 5.14E+11 | |
| 238 | P2 | 1 | 1 | 150 | 120 | 1.01E+14 | |
| 239 | P4 | 1 | 1 | 150 | 120 | 4.44E+13 | |
| 240 | P4 | 12 | 1 | 150 | 110 | 4.48E+13 | |
| 241 | P5 | 1 | 1 | 150 | 120 | 1.40+E14 | |
| 242 | P5 | 12 | 1 | 150 | 110 | 1.35E+14 | |
| 243 | P6 | 1 | 1 | 150 | 120 | 2.73E+14 | |
| 244 | P6 | 12 | 1 | 150 | 110 | 3.62E+14 | |
| 245 | P6 | 12 | 1 | 15 | 110 | 1.21E+14 | |
| 246 | P6 | 9 | 1 | 30 | 90 | 4.51E+12 | Aqueous |
| | | | | | | | solution |
| 247 | P7 | 1 | 1 | 150 | 120 | 2.51E+13 | |
| 248 | P7 | 12 | 1 | 150 | 110 | 5.38E+13 | |
| 249 | P8 | 1 | 1 | 150 | 120 | 7.51E+13 | |
| 250 | P9 | 12 | 1 | 150 | 110 | 3.80E+14 | |
| 251 | P10 | 12 | 1 | 150 | 110 | 3.52E+14 | |
| 252 | P10 | 12 | 1 | 15 | 110 | 5.15E+14 | |
| 253 | P10 | 12 | 0.1 | 15 | 110 | 5.00E+14 | |
| 254 | P10 | 12 | 1 | 60 | 60 | 1.51E+14 | |
| 255 | P10 | 12 | 1 | 5 | 70 | 5.06E+12 | |
| 256 | P10 | 12 | 1 | 15 | 70 | 6.65E+13 | |
| 257 | P10 | 12 | 1 | 60 | 70 | 1.60E+14 | |
| 258 | P10 | 12 | 1 | 150 | 70 | 2.37E+14 | |
| 259 | P10 | 12 | 1 | 5 | 80 | 1.03E+14 | |
| 260 | P10 | 12 | 1 | 10 | 80 | 1.68E+14 | |
| 261 | P10 | 12 | 1 | 15 | 80 | 1.50E+14 | |
| 262 | P10 | 12 | 1 | 30 | 80 | 2.23E+14 | |
| 263 | P10 | 12 | 1 | 60 | 80 | 1.91E+14 | |
| 264 | P10 | 12 | 1 | 150 | 80 | 2.92E+14 | |
| 265 | P11 | 12 | 1 | 150 | 110 | 1.27E+13 | |
| 266 | P11 | 12 | 1 | 150 | 110 | 8.98E+11 | |

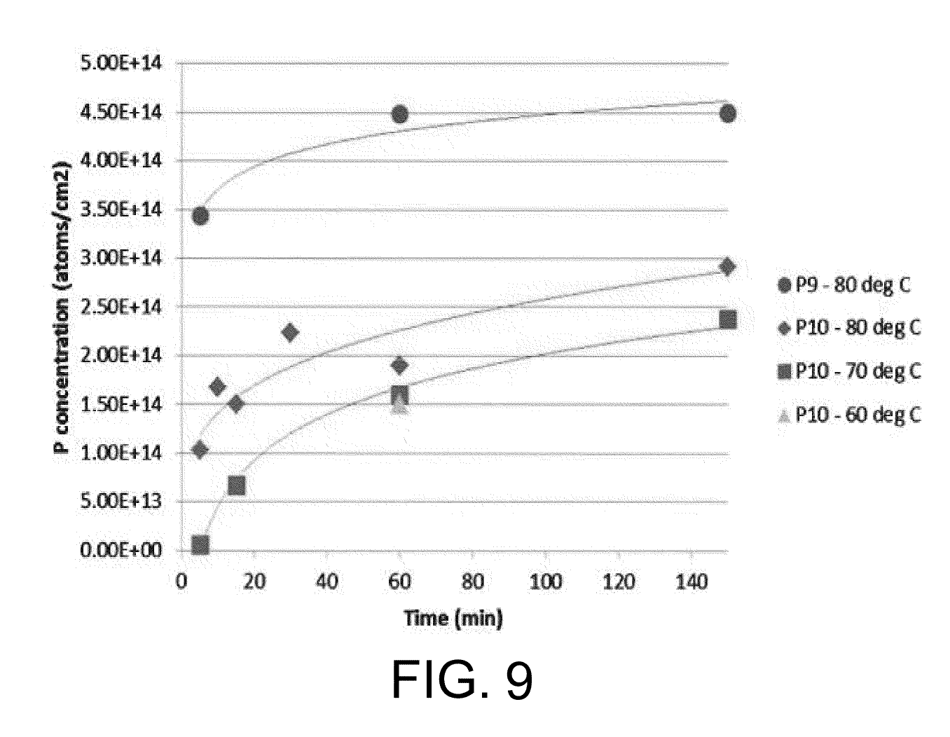

FIG. 9 includes a graph showing changes in concentration of phosphorus atoms attached to atoms of a surface of a substrate that includes a semiconductor material as a function of time according to different temperatures and for dopant solutions including different phosphorous-containing molecules. FIG. 9 shows results using P9 (phosphorous acid) or P10 (phosphoric acid) as the dopant and DB acetate as the solvent in the dopant solution with the concentration of P9 or P10 being about 1%. The graph generally shows that increasing the reaction temperature results in increased binding of phosphorus atoms to atoms of the silicon surface.

### Dopant Solution Degradation Examples

Experiments were done to ascertain the lifetime of several doping solutions. In one experiment, 2.0 wt % solutions of dopants 11, 12, and 15 in solvent S1 (tetraglyme) were prepared in vials. For each dopant, three vials were prepared: one vial was left loosely capped to allow air in and out of the vial; one was tightly sealed, and one had the headspace purged with N₂ prior to tightly sealing it. Three vials containing only tetraglyme were similarly prepared. The vials were heated at 120° C., and samples were regularly withdrawn for analysis by gas chromatography (GC).

Analysis of the samples containing only tetraglyme showed that the tetraglyme initially had traces of organic impurities. Heating the tetraglyme in a sealed vial at 120° C. for 11 days only increased the amounts of impurities slightly. The sample in which the headspace was purged with N₂ showed similar behavior. However, the sample containing a loose cap, allowing air in and out of the vial, showed a large amount of decomposition products. Thus, in order to keep tetraglyme from decomposing at 120° C., it must be kept away from contact with air.

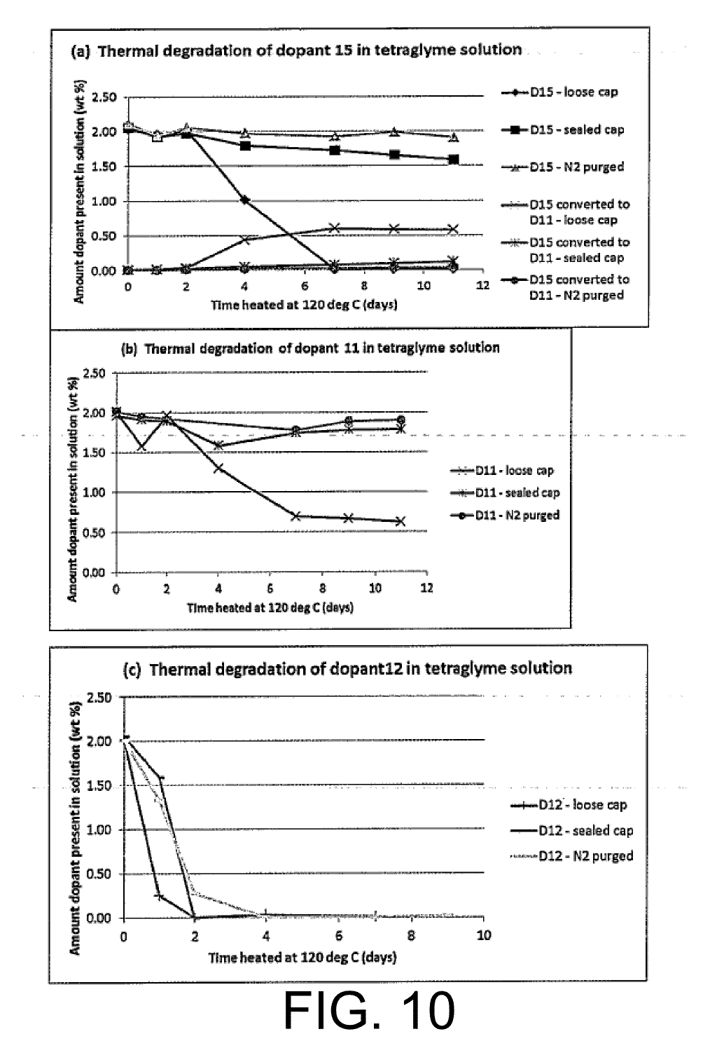

The samples containing the dopants were similarly analyzed by GC, and the amount of dopant present was quantified in FIG. 10 which shows an amount of dopant present after heating a vial of (a) dopant 15, (b) dopant 11, and (c) dopant 12. In particular, FIG. 10 includes a first graph showing the degradation of an amount of a first dopant in a tetraglyme solution over time, a second graph showing the degradation of an amount of a second dopant in a tetraglyme solution over time, and a third graph showing the degradation of an amount of a third dopant in a tetraglyme solution over time. For dopant 15, the vial whose headspace was purged with N₂ showed very little decomposition, whereas the vial with a sealed cap showed slightly more decomposition. The loosely capped vial showed complete decomposition of dopant 15 within 7 days, showing that presence of large amounts of air speeds up the decomposition. This is likely due to the presence of moisture in the air, since a significant amount of dopant 15 in this vial was hydrolyzed to dopant 11.

The N₂ purged and sealed vials containing dopant 11 showed behavior similar to that of dopant 15. However, the loosely capped vial of dopant 11 still had about 30% of the dopant present after 11 days.

Solutions of dopant 12 are much less thermally stable. In all three vials, the dopant had completely decomposed within 4 days, although the same trend—fastest decomposition in the loosely capped vial, slowest decomposition in the N₂ purged vial—was observed.

A sample of freshly synthesized dopant 12 was analyzed by NMR, and it showed the presence of a small amount of hydrolyzed ligand (2-hydroxyisobutyric acid, HO—C(CH₃)₂—COOH). A sample of dopant 12 was kept in a loosely capped vial at room temperature for 12 days. NMR analysis of this sample proved that it was similar to the freshly prepared sample, indicating that little hydrolysis or decomposition had occurred. Another sample of dopant 12 was placed in a capped vial together with some water to form a slurry. After 12 days, NMR analysis of this sample showed that dopant 12 had completely hydrolyzed, and 2-hydroxyisobutyric acid was present.

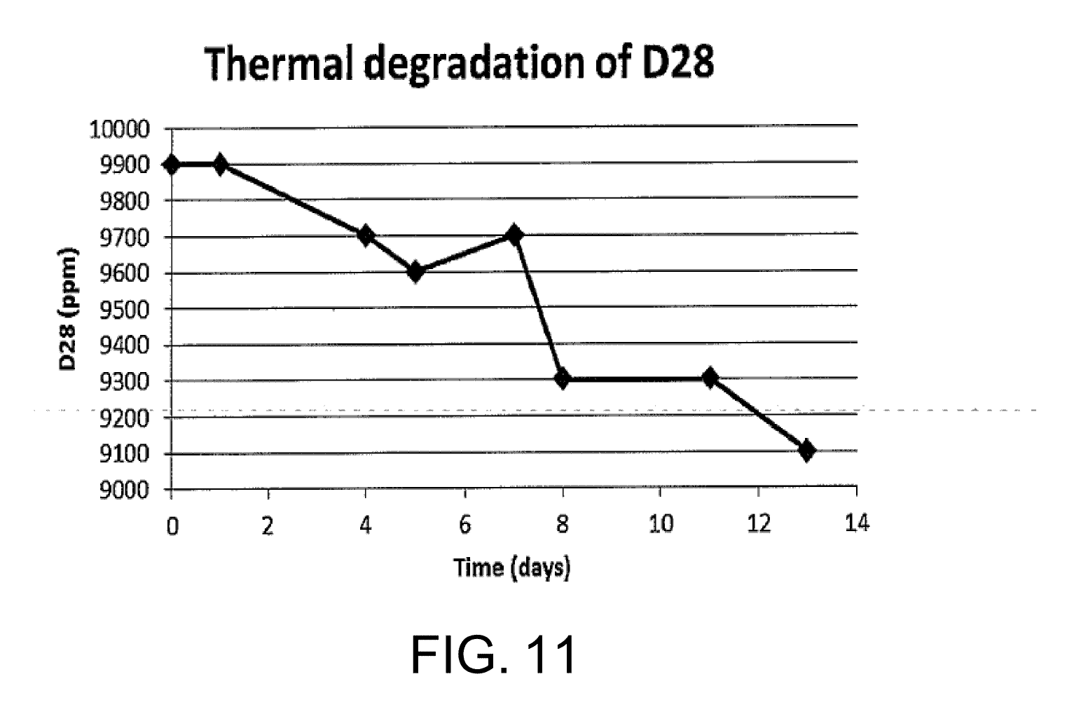

In another experiment, a 1% solution of dopant 28 (4-hydroxyphenylarsonic acid) in solvent S1 (tetraglyme) was prepared, and heated in a tightly sealed vial at 110° C. Samples were periodically withdrawn and analyzed by liquid chromatography. Over a period of 13 days, approximately 8% of dopant 28 decomposed as shown in FIG. 11. In particular, FIG. 11 includes a graph showing the degradation of an amount of a fourth dopant in a tetraglyme solution over time. This suggests that a solution of dopant 28 could be used for an extended period of time.

In another experiment, a solution containing dopant 36 (arsenic acid) in solvent S12 (DB Acetate) was prepared in a kettle, and after processing a silicon coupon in the normal manner, the kettle with the solution was kept heated at 110° C. for five days, with nitrogen continuously bubbling through the system. At 2 days and 5 days, additional silicon coupons were processed in the solution, using the same time and temperature conditions as the initial coupon. As shown in Table 8, the arsenic dose on all three coupons is the same within the limits of the analysis technique. Samples of the solution were also withdrawn before heating and when removing each of the three coupons. The amount of arsenic present (analyzed as the arsenate anion) was determined by ion chromatography, and remained approximately constant over the course of five days (Table 9). This shows that the dopant does not volatilize from the solution. GC-MS of the same samples showed that small amounts of organic impurities were initially present in the solution. Upon heating at 110° C. for five days, the profile of the organic impurities shifted to contain more high-boiling compounds and less low-boilers, but overall the amount of impurities only increased slightly, indicating that the solvent does not undergo significant decomposition over the period of five days under processing conditions. This experiment shows that a solution of dopant 36/solvent S12 can be used for at least five days, and possibly longer.

TABLE 8
Arsenic concentration on silicon coupons processed in the same solution
of dopant 36 (1.0% triethylarsenate, 0.29% water) in solvent S12 for
60 minutes at 110° C. In between, the solution was kept at 110° C.

| | | Arsenic dose |
|---|---|---|
| Experiment No. | Description | (atoms/cm²) |
| 267 | Si coupon with fresh solution | 3.69E+14 |
| 268 | Si coupon after heating 2 days | 3.46E+14 |
| 269 | Si coupon after heating 5 days | 3.16E+14 |

TABLE 9
Ion chromatography of the dopant 36/solvent S12 solution
used for the runs listed in Table 8.

| Experiment | | Arsenate concentration |
|---|---|---|
| No. | Description | (wt %) |
| 270 | Initial solution before heating | 0.67 |
| 271 | Solution after heating ~3 hours | 0.68 |
| 272 | Solution after heating 2 days | 0.71 |
| 273 | Solution after heating 5 days | 0.70 |

### Contaminant Examples

Silicon wafers were processed in a class 100 cleanroom using the MLD process. To process a wafer with the arsenic MLD method, it was first immersed in 0.5% HF for 2 minutes, followed by immersion in water for 30 seconds. The wafer was then blown dry with nitrogen, and placed in a glass kettle ˜13 inches in diameter and ˜3 inches high. The doping solution (500 mL dopant 36/solvent S12) was added, and the kettle was sealed with a Teflon lid with three ports—a nitrogen inlet, a nitrogen outlet, and a thermocouple. The kettle was heated at 110° C. for 15 minutes under a flow of nitrogen. The wafer was then removed, immersed in isopropanol for 1 minute, further rinsed with a stream of isopropanol for 1 minute, and then blown dry with nitrogen. The wafer was analyzed by total reflection x-ray fluorescence (TXRF) analysis.

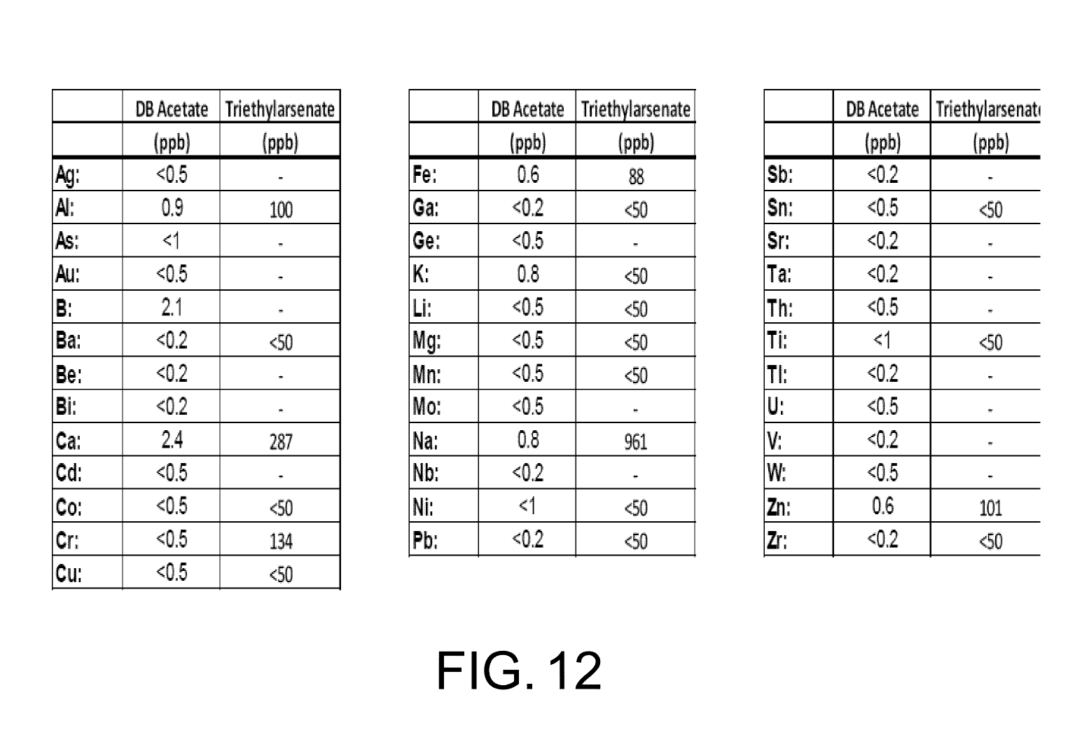

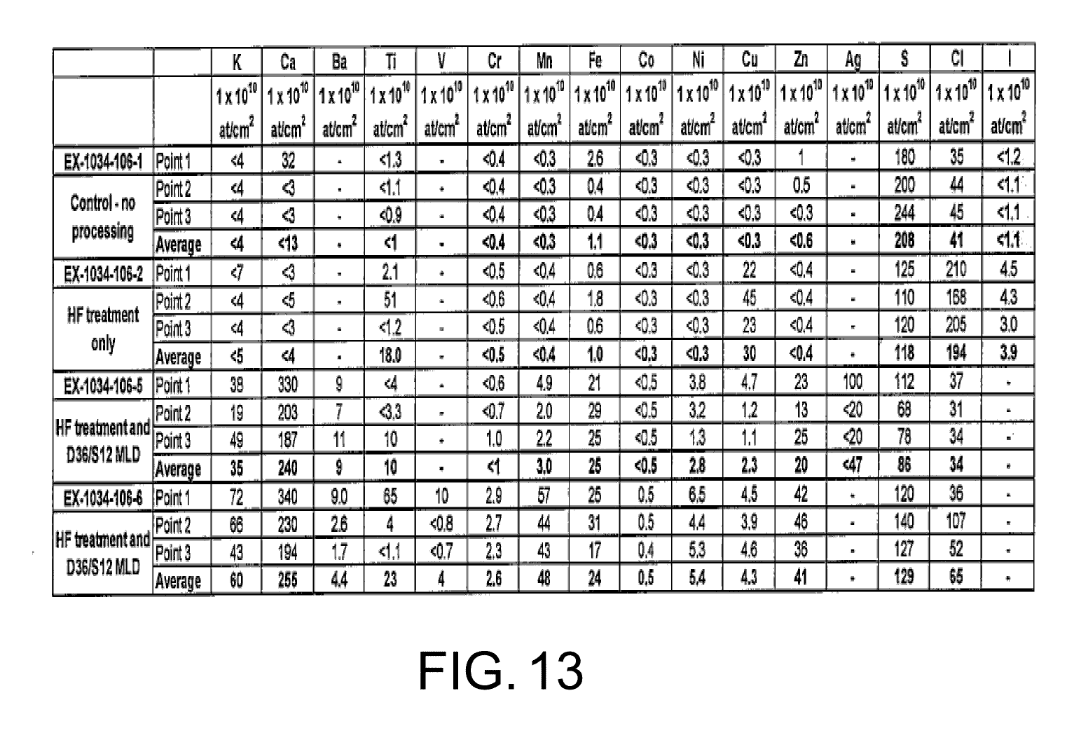

The water, hydrofluoric acid, and isopropanol were all electronic grade (the water used for wafer EX-1034-106-2 was found to contain elevated levels of copper, which is reflected in the TXRF results). The trace metal analyses for solvent S12 and triethylarsenate are given in FIG. 12. In particular, FIG. 12 includes a first table, a second table, and a third table showing amounts of trace elements in a dopant solution including triethylarsenate and DB acetate. The TXRF results for trace metals are provided in FIG. 13. In particular, FIG. 13 includes a table showing amounts of trace elements in silicon wafers under different processing conditions. TXRF mapping of the arsenic concentration was performed for several wafers and indicates that arsenic can be deposited on a 300 mm wafers with good uniformity (5-10% relative standard deviation).

The ability to deposit the dopant on a wafer surface with minimal contamination of the wafer surface is critical to the use of this method by the semiconductor industry.

What is claimed is:

1. A solution comprising:
a solvent having a flashpoint of at least about 55° C.; and
a dopant-containing molecule including a Group 15 element, wherein a molecular weight of the dopant-containing molecule is no greater than about 300 g/mol, and the Group 15 element includes arsenic or phosphorus.

2. The solution of claim 1, wherein the solvent includes a glycol, a glycol ether, a glycol diether, a carboxylate of a glycol ether, or a combination thereof.

3. The solution of claim 1 wherein the solvent includes diethylene glycol monobutyl ether acetate or tetraethylene glycol dimethyl ether.

4. The solution of claim 1, wherein the dopant-containing molecule includes an acid group.

5. The solution of claim 1, wherein a dopant of the dopant-containing molecule includes phosphorus and has a molecular weight no greater than 175 g/mol.

6. The solution of claim 1, wherein the dopant-containing molecule includes arsenic acid.

7. The solution of claim 1, wherein the dopant-containing molecule includes phosphoric acid or phosphorous acid.

8. The solution of claim 1, further comprising an additive.

9. The solution of claim 8, wherein the additive includes a corrosion inhibitor, an antioxidant, a catalyst, a trace metal chelator, or a surface modifier.

10. A solution comprising:
a dopant-containing molecule having a group 15 element including arsenic or phosphorus;
a solvent; and
a contaminant;
wherein a ratio of a concentration by weight of a dopant-containing molecule relative to a concentration by weight of a contaminant is no greater than about 1×10¹⁰.

11. The solution of claim 10, wherein a concentration of the dopant-containing molecule is no greater than about 10% by weight of a total weight of the solution.

12. The solution of claim 10, wherein a concentration of the dopant-containing molecule is included in a range of about 0.01% by weight of a total weight of the solution to about 1% by weight of a total weight of the solution.

13. The solution of claim 10, wherein the contaminant includes a metal

14. The solution of claim 13, wherein the metal includes copper.

15. The solution of claim 10, wherein the contaminant is one of a plurality of contaminants of the solution, and a concentration of the plurality of contaminants is no greater than about 20 parts per billion.

16. The solution of claim 10, wherein a concentration of the contaminant is no greater than 3 parts per billion.

17. The solution of claim 10, wherein the solvent includes diethylene glycol monobutyl ether acetate, diethylene glycol monobutyl ether, tetraethylene glycol dimethyl ether, dimethylsulfoxide, water, N-methylpyrrolidone, mesitylene, or a combination thereof.

18. The solution of claim 10, wherein the solvent includes diethylene glycol monobutyl ether acetate or or tetraethylene glycol dimethyl ether.

19. The solution of claim 10, wherein the dopant-containing molecule includes phosphorus and the contaminant includes arsenic.

20. The solution of claim 10, wherein the dopant-containing molecule includes arsenic and the contaminant includes phosphorus.

21. A process comprising:
preparing a solution including a dopant-containing molecule and a solvent, the dopant-containing molecule including a Group 15 element and the dopant-containing molecule having a molecular weight no greater than 300 g/mol, wherein the Group 15 element includes phosphorus or arsenic; and
contacting a substrate with the solution to cause individual instances of the dopant-containing molecule to bond with respective atoms of a semiconductor material at a surface of the substrate.

22. The process of claim 21, wherein the substrate is contacted with the solution for a duration included in a range of about 1 minute to about 150 minutes.

23. The process of claim 21, wherein a temperature of the solution is included in a range of about 50° C. to about 150° C. while contacting the substrate with the solution.

24. The process of claim 21, wherein the substrate is contacted with the solution in a nitrogen environment or an argon environment.

25. The process of claim 21, further comprising removing an oxide layer from the substrate before contacting the substrate with the solution.

26. The process of claim 21, wherein the semiconductor material includes silicon, germanium, or a combination thereof.

27. The process of claim 21, wherein a concentration of individual instances of dopant atoms attached to the respective atoms of the semiconductor material is at least about 1×10¹⁴ atoms/cm².

28. The process of claim 21, wherein a concentration of the dopant-containing molecule in the solution is no greater than 5% by weight of a total weight of the solution.

29. The process of claim 21, wherein contacting the substrate with the solution includes immersing the substrate in the solution.

30. The process of claim 21, wherein contacting the substrate with the solution includes coating at least one surface of the substrate with the solution.

31. The process of claim 21, wherein the substrate further comprises:
a planar substrate surface;
an additional substrate surface having one or more topographic features; or
a combination thereof.

32. The process of claim 31, wherein at least a portion of the planar substrate surface, at least a portion of the additional substrate surface, or both include a layer of a patterned material.

33. The solution of claim 1, wherein the dopant-containing molecule includes
a composition of matter comprising
a compound selected from a group consisting of:
(a) 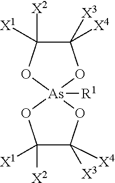
Wherein R¹ is 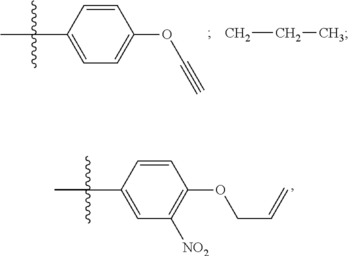
and x₁-x₄ are CH₃;
Wherein R¹ is 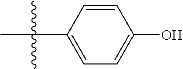 [SMILES: *c1ccc(O)cc1]
and x₁-x₄ are H;
Wherein R¹ is CH₂—CH═CH₂ or 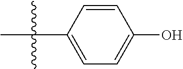 [SMILES: *c1ccc(O)cc1]
and when x₁ and x₃ are replaced by a double bond, x₂, x₄, and 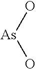
can form a ring structure of 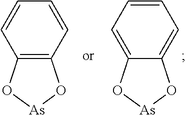
(b) 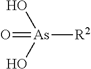
wherein R² is selected from the following: 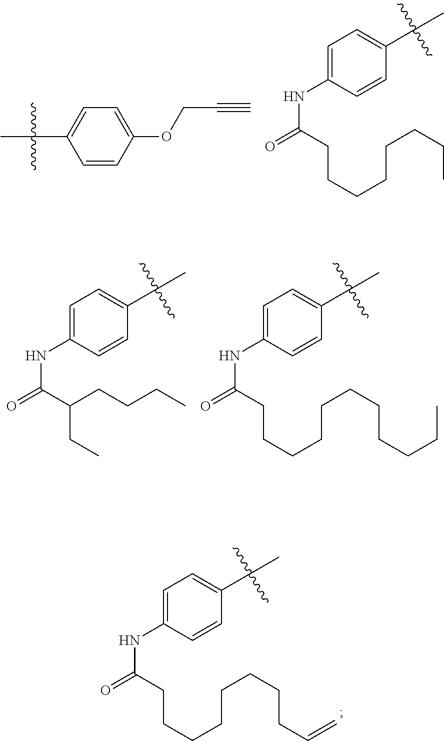
and
(c) 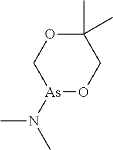
and (d) 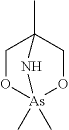
and (e) [chemical structure]
